(19) United States
(12) Patent Application Publication
(10) Pub. No.: US 2025/0349691 A1
(43) Pub. Date: Nov. 13, 2025

(54) SEMICONDUCTOR DEVICE AND METHOD

(71) Applicant: Taiwan Semiconductor Manufacturing Co., Ltd., Hsinchu (TW)

(72) Inventors: Chih Hsin Yang, Zhubei (TW); Yun-Sheng Li, Hsinchu (TW)

(21) Appl. No.: 19/276,810

(22) Filed: Jul. 22, 2025

Related U.S. Application Data
(63) Continuation of application No. 18/655,999, filed on May 6, 2024.
(60) Provisional application No. 63/613,140, filed on Dec. 21, 2023.

(51) Int. Cl. H01L 23/498; H01L 21/48; H01L 21/768; H01L 23/528; H01L 23/58

(52) U.S. Cl. CPC H01L 23/49827; H01L 21/4853; H01L 21/486; H01L 21/76895; H01L 23/49811; H01L 23/5283; H01L 23/585

(57) ABSTRACT

In an embodiment, a device may include a first structure comprising a first surface and a second surface opposite the first surface. The first structure may include a first substrate and a first through substrate via (TSV) exposed from the second surface of the first substrate. The first TSV may have a first width. The device may also include a second TSV exposed from the second surface of the first structure, where the second TSV has a second width smaller than the first width. The device may further include a guard ring surrounding each of the first and second TSVs. Additionally, the device may include a second structure bonded to the first surface of the first structure, where the first surface has first bond pads.

### PRIORITY CLAIM AND CROSS-REFERENCE

This application is a continuation of U.S. patent application Ser. No. 18/655,999, filed May 6, 2024, which claims the benefit of U.S. Provisional Application No. 63/613,140 filed on Dec. 21, 2023, entitled “Semiconductor Package and Method of Manufacturing the Same,” which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, and 9 illustrate cross-sectional views and plan views of intermediate stages in the formation of a die according to embodiments.

FIGS. 10, 11, 12, 13, 14, 15, 16, 17, 18, 19, 20, and 21 illustrate cross-sectional views of intermediate stages in the formation of stacked packages in accordance with some embodiments.

FIGS. 22A, 22B, 23A, 23B, 24A, 24B, 25, 26, 27A, 27B, 28A, and 28B illustrate cross-sectional views and plan views of various packages in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein may be discussed in a specific context, namely a device/structure with through substrate vias (TSVs) of different sizes. For example, a device could have larger TSVs (e.g., wider in a cross-sectional view) used for power and ground, and smaller TSVs (e.g., narrower in cross-sectional view) used for signal delivery. The disclosed device and method provide a solution that allows for both power and signal delivery, thereby enabling multi-stacking and offering a more flexible design.

The size of the TSVs, also known as the TSV critical dimension (CD), can affect the performance of the TSVs. Large TSV CDs are good for face-to-face (F2F) power delivery due to their low resistance, while small TSV CDs are good for face-to-back (F2B) die-to-die (D2D) communications due to their small pitch. However, both large and small TSV CDs have their drawbacks. Large TSV CDs cause high RC delay for signal communication, and small TSV CDs result in a high IR drop for power delivery. These issues constrained the design of System-on-Integrated-Circuit (SoIC) stacking, whether in a F2F or F2B configuration.

The disclosed device and method overcome these challenges by incorporating different TSV CDs in a single solution for both power and signal delivery. This approach allows for multi-stacking beyond just two-tier stacking, providing a more flexible design. Within a single tier, at least two different TSV CDs are formed to enable different SoIC stacking combinations, such as F2F and multiple F2B multi-stacking.

The disclosed device and method offer several advantages. They provide a more friendly design with less TSV area overhead. They offer an all-in-one solution for TSVs, making them an ideal solution for various package types. Furthermore, they enable high signal bandwidth, high-speed interconnects, and high-density integration for computing and high-power applications, such as Artificial Intelligence (AI) applications or deep learning.

Further, the teachings of this disclosure are applicable to any device or package with TSVs in a stacked package arrangement. Other embodiments contemplate other applications, such as different package types or different configurations that would be readily apparent to a person of ordinary skill in the art upon reading this disclosure. It should be noted that embodiments discussed herein may not necessarily illustrate every component or feature that may be present in a structure. For example, multiples of a component may be omitted from a figure, such as when discussion of one of the components may be sufficient to convey aspects of the embodiment. Further, method embodiments discussed herein may be discussed as being performed in a particular order; however, other method embodiments may be performed in any logical order.

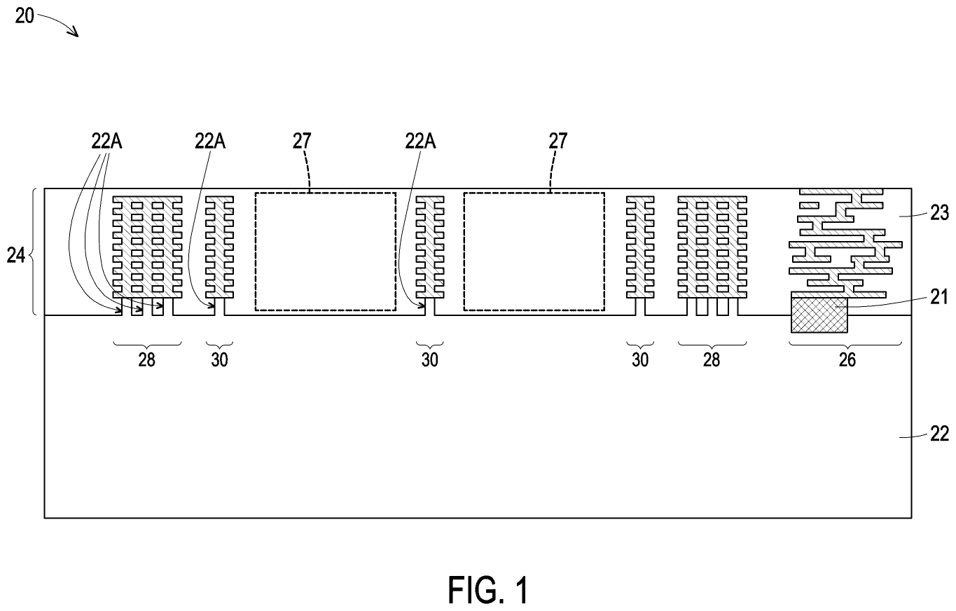

FIGS. 1, 2, 3, 4, 5, 6, 7, 8, and 9 illustrate cross-sectional views of intermediate stages in the formation of a die or wafer 20 in accordance with some embodiments.

FIG. 1 illustrates a cross-sectional of an integrated circuit die 20 in accordance with some embodiments. While the structure 20 is described as a die in the following description, the structure 20 may be a wafer 20 and not singulated after the formation steps.

The integrated circuit die 20 will be packaged in subsequent processing to form an integrated circuit package. The integrated circuit die 20 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 20 may be formed in a wafer, which may include different device regions that are singulated in subsequent steps to form a plurality of integrated circuit dies. The integrated circuit die 20 may be processed according to applicable manufacturing processes to form integrated circuits. For example, the integrated circuit die 20 includes a substrate 22, such as silicon, doped or undoped, or an active layer of a semiconductor-on-insulator (SOI) substrate. The substrate 22 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 22 has an active surface (e.g., the surface facing upwards in FIG. 1), sometimes called a front side, and an inactive surface (e.g., the surface facing downwards in FIG. 1), sometimes called a back side.

Devices 21 may be formed at the front surface of the substrate 22. The devices 21 may be active devices (e.g., transistors, diodes, etc.), capacitors, resistors, the like, or a combination thereof. An inter-layer dielectric (ILD) (not separately illustrated) is over the front surface of the substrate 22. The ILD surrounds and may cover the devices 21. The ILD may include one or more dielectric layers formed of materials such as Phospho-Silicate Glass (PSG), Boro-Silicate Glass (BSG), Boron-Doped Phospho-Silicate Glass (BPSG), Undoped Silicate Glass (USG), or the like.

Conductive plugs (not separately illustrated) extend through the ILD to electrically and physically couple the devices 21. For example, when the devices 21 are transistors, the conductive plugs may couple the gates and source/drain regions of the transistors. The conductive plugs may be formed of tungsten, cobalt, nickel, copper, silver, gold, aluminum, the like, or combinations thereof.

The active surface of the substrate 22 includes portions 22A between the substrate 22 and dummy metallization pattern 28 and the guard ring 30. These portions 22A may be patterned portions of the substrate 22 or may be structures formed on top of the substrate 22. These portions extend as high as the front-end-of-line processing of the substrate 22. In some embodiments, the front-end-of-line processing ends after the gate, ILD, and conductive plug formation.

An interconnect structure 24 is over the ILD and the conductive plugs. The interconnect structure 24 may be formed by, for example, metallization patterns 26, 28, 30 in dielectric layers 23 on the ILD. In these embodiments, the metallization patterns 26, 28, 30 are formed in the middle-end-of line and the back-end-of line processing. The metallization patterns 26, 28, 30 include metal lines and vias formed in one or more low-k dielectric layers 23. The metallization patterns may be formed using any suitable process, such as a single damascene process, a dual damascene process, a plating process, combinations thereof, or the like.

The metallization patterns 26, 28, 30 include active metallization patterns 26, guard rings 30, and optionally dummy metallization patterns 28. The active metallization patterns 26 of the interconnect structure 24 interconnects the devices to form an integrated circuit. The active metallization patterns 26 are electrically coupled to the devices by the conductive plugs. The dummy metallization pattern 28 is electrically isolated from the devices of the die 20.

As illustrated in FIG. 1, the guard rings 30 are formed around TSV areas 27. The guard ring 30 may be separate guard rings 30 around adjacent TSV areas 27 or a single guard ring 30 (as illustrated between areas 27 in FIG. 1) may be formed between adjacent areas 27. The dummy metallization patterns 28, if present, may be formed adjacent the guard rings 30 or the active metallization patterns 26. The dummy metallization patterns 28 and the guard rings 30 are formed simultaneously and by the same processes as the active metallization patterns 26. The guard rings 30 can reduce the leakage current between the subsequently formed TSVs and the substrate 22 and other structures in the interconnect structure 24. In addition, TSVs can introduce mechanical stress and the guard rings 30 can provide stress relief during the fabrication and operation of the device. Further, the guard rings 30 can provide electrical isolation between the TSVs and nearby active devices and metallization patterns. The dummy metallization patterns 28 are included to provide a more uniform pattern density in the interconnect structure 24 which can help with planarization and process consistency, such as during a chemical mechanical polishing (CMP) process.

In some embodiments, the guard rings 30 surround each of the TSV areas 27 and the dummy metallization patterns 28 surround the guard rings 30 and are not between the TSV areas 27. In some embodiments, the dummy metallization patterns 28 could be between the TSV areas 27.

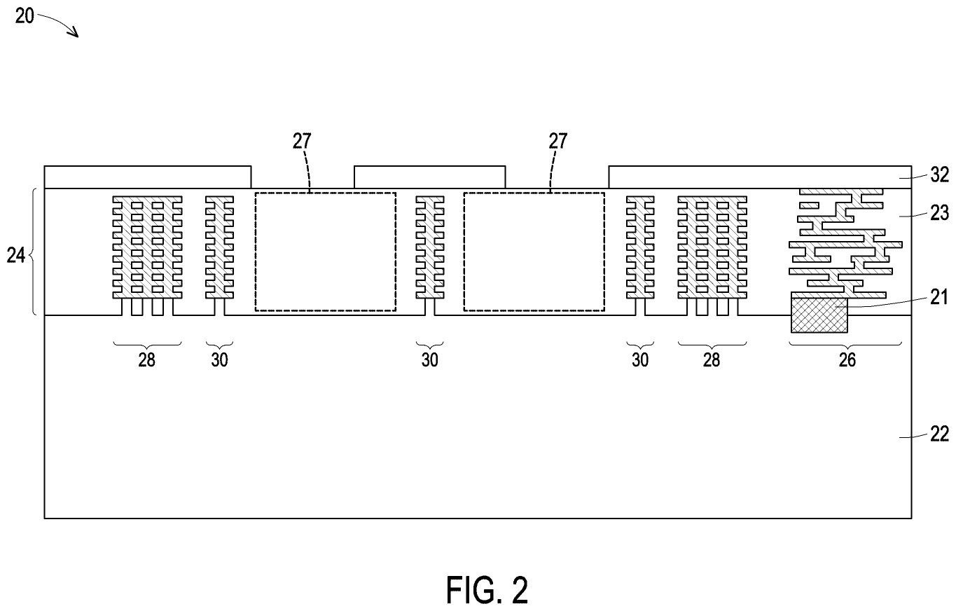

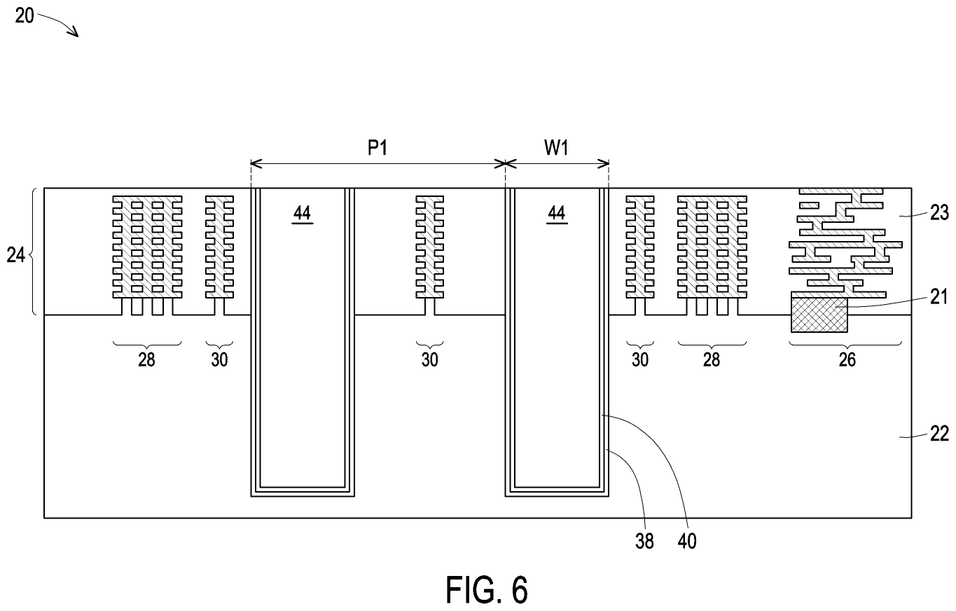

After forming the interconnect structure 24, as shown in FIG. 2, a mask 32 is formed and patterned on the interconnect structure 24. In some embodiments, the mask 32 is a photoresist and may be formed by spin coating or the like and may be exposed to light for patterning. The pattern of the photoresist corresponds to the subsequently formed through substrate via (TSV) 44 (see, e.g., FIG. 6) in the TSV areas 27. The patterning forms at least one opening through the photoresist 32 to expose the interconnect structure 24. In some embodiments, a stop layer (not shown), such as a chemical mechanical polishing (CMP) stop layer is deposited over a top surface of the interconnect structure 24 before the mask 32. The CMP stop layer may be used to prevent a subsequent CMP process from removing too much material by being resistant to the subsequent CMP process and/or by providing a detectable stopping point for the subsequent CMP process. In some embodiments, the CMP stop layer may comprise one or more layers of dielectric materials. Suitable dielectric materials may include oxides (such as silicon oxide, aluminum oxide, or the like), nitrides (such as SiN, or the like), oxynitrides (such as SiON, or the like), oxycarbides (such as SiOC, or the like), carbonitrides (such as SiCN, or the like), carbides (such as SiC, or the like), combinations thereof, or the like, and may be formed using spin-on coating, chemical vapor deposition (CVD), plasma-enhanced CVD (PECVD), atomic layer deposition (ALD), the like, or a combination thereof.

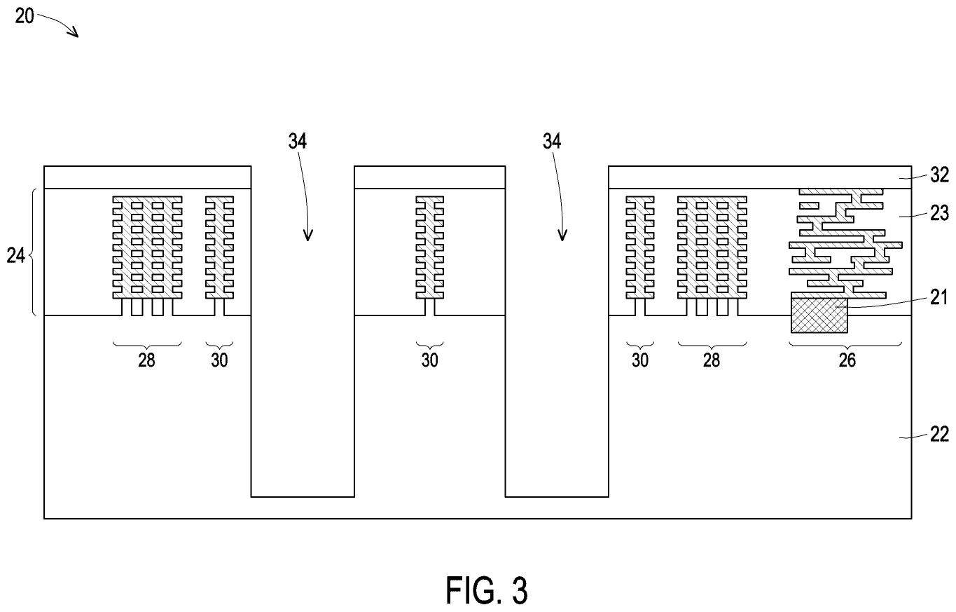

In FIG. 3, the remaining mask 32 is used as a mask during an etching process to remove exposed and underlying portions of the dielectric layer(s) 23 of the interconnect structure 24 and the substrate 22. A single etch process may be used to etch openings 34 in the TSV areas 27 of the interconnect structure 24 and the substrate 22 or a first etch process may be used to etch the interconnect structure 24 and a second etch process may be used to etch the substrate 22. In some embodiments, the opening 34 is formed with a plasma dry etch process, and a reactive ion etch (RIE) process, such as a deep RIE (DRIE) process. In some embodiments, the DRIE process includes etch cycle(s) and passivation cycle(s) with the etch cycle(s) using, for example, SF₆, and the passivation cycle(s) using, for example, C₄F₈. The utilization of a DRIE process with the passivation cycle(s) and the etch cycle(s) enables a highly anisotropic etching process. In some embodiments, the etch process(es) may be any acceptable etching process, such as by wet or dry etching.

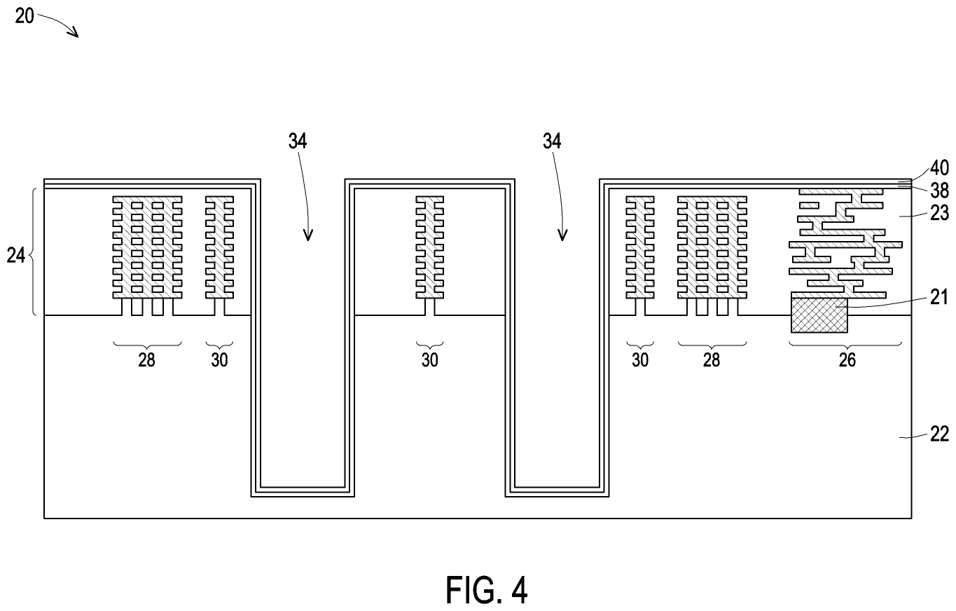

As illustrated in FIG. 4, after forming the openings 34, the photoresist 32 is removed. The photoresist 32 may be removed by an acceptable ashing or stripping process, such as using an oxygen plasma or the like.

Further in FIG. 4, a liner layer 38 is conformally deposited on the interconnect structure 24 and on bottom surfaces and sidewalls of the openings 34. In some embodiments, the liner layer 38 includes one or more layers of dielectric materials and may be used to physically and electrically isolate the subsequently formed through vias from the substrate 22. Suitable dielectric materials may include oxides (such as silicon oxide, aluminum oxide, or the like), nitrides (such as SiN, or the like), oxynitrides (such as SiON, or the like), combinations thereof, or the like. The liner layer 38 may be formed using CVD, PECVD, ALD, the like, or a combination thereof.

In a subsequent step, as shown in FIG. 4, a seed layer 40 is formed over liner layer 38. In some embodiments, the seed layer 40 is a metal layer, which may be a single layer or a composite layer comprising a plurality of sub-layers formed of different materials. In some embodiments, the seed layer 40 comprises a titanium layer and a copper layer over the titanium layer. The seed layer may be formed using, for example, physical vapor deposition (PVD) or the like. In some embodiments, a barrier layer (not shown) may be formed on the liner layer 38 prior to forming the seed layer 40. The barrier layer may comprise Ti, TiN, the like, or a combination thereof.

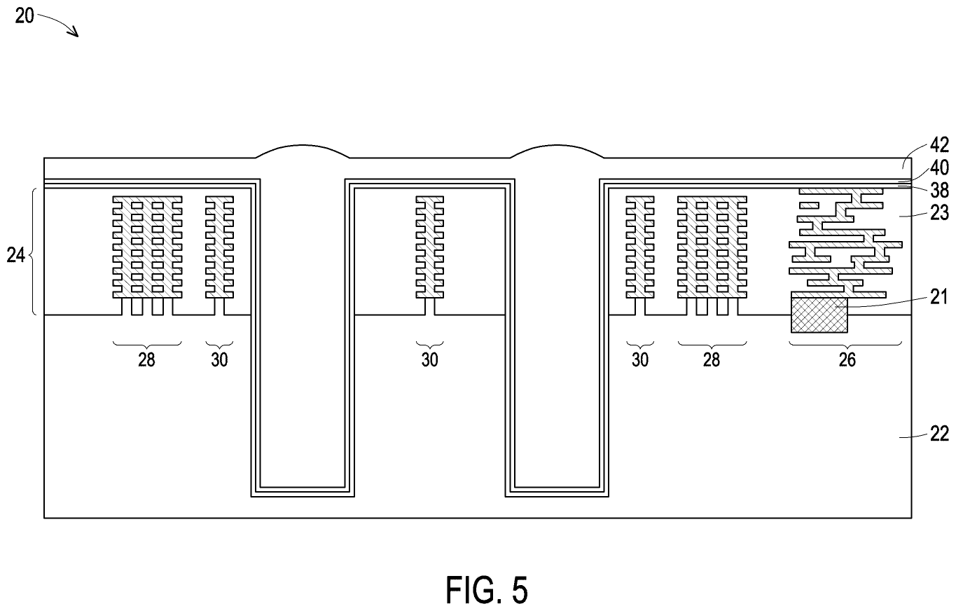

In FIG. 5, a conductive material 42 is formed on the seed layer 40 and fills the openings 34. The conductive material 42 may be formed by plating, such as electroplating including electrochemical plating, electroless plating, or the like. The conductive material may comprise a metal, like copper, titanium, tungsten, aluminum, or the like.

After the conductive material 42 is formed, an anneal process is then performed. The anneal process may be performed to prevent subsequent extrusion of the conductive material of the TSV 44 (sometime referred to as TSV pumping). The TSV pumping is caused by a coefficient of thermal expansion (CTE) mismatch between the conductive material 42 and the substrate 22 and can cause damage to structures (e.g., metallization patterns) over the TSV.

Following the anneal process, a planarization process is performed to remove portions of the conductive material 42, the seed layer 40, and the liner layer 38 outside the openings 34 to form TSVs 44 as illustrated in FIG. 6. Top surfaces of the TSV 44 and the topmost dielectric layer of the interconnect structure 24 are coplanar after the planarization process within process variations. The planarization process may be, for example, a chemical-mechanical polish (CMP), a grinding process, or the like. In some embodiments, the upper portion of the TSV 44 (formed in the interconnect structure 24) has a greater width than the lower portion of the TSV 44 (formed in the substrate 22). In some embodiments, the width of the TSV 44 is constant through the interconnect 24 and the substrate 22. In some embodiments, the TSVs 44 are formed to have a width W1. In some embodiments, the width W1 is less than 15 μm. In some embodiments, the TSVs 44 are formed to have a pitch P1. In some embodiments, the pitch P1 is in a range from (1×W1) to (2×W1). In some embodiments, the pitch P1 is in a range from 4 μm to 10 μm.

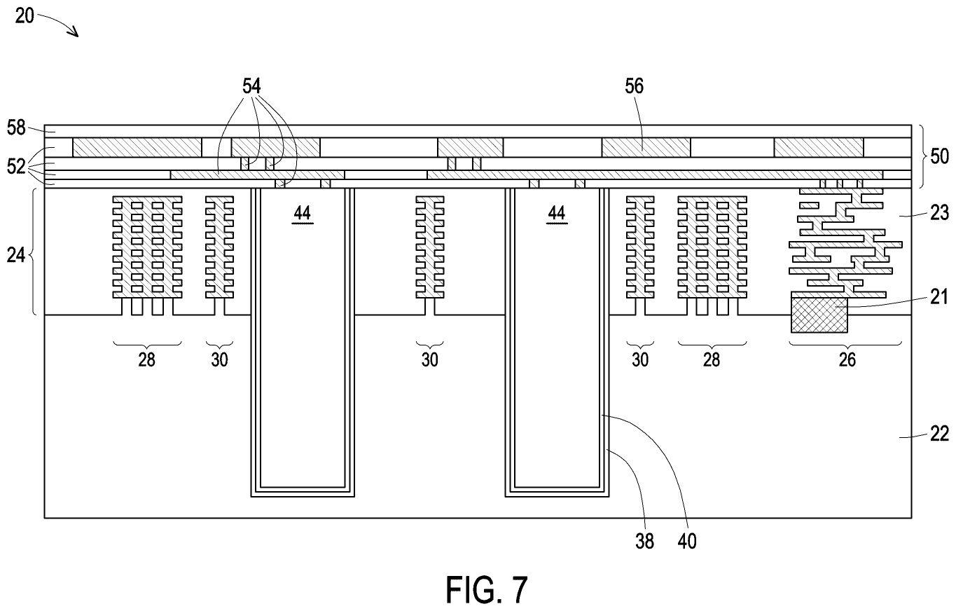

Referring to FIG. 7, an interconnect structure 50 is formed over the structure of FIG. 6. The interconnect structure 50 includes dielectric layers 52, metallization patterns and vias 54, and top metal 56. More or fewer dielectric layers and metallization patterns and vias may be formed than is shown in FIG. 7. The interconnect structure 50 is connected to the active metallization patterns 26 of the interconnect structure 24 and TSV 44 by metallization patterns and vias formed in the dielectric layer(s) 52. The metallization patterns and vias may be formed similar processes and materials as the interconnect structure 24 and the description is not repeated herein. In some embodiments, there are more than one layer of top metal 56, such as two top metal layers.

In some embodiments, the dielectric layers 52 are a same material as the dielectric layers 23 of the interconnect structure 24, e.g., low-k dielectric. In other embodiments, the dielectric layers 52 are formed of a silicon-containing material (which may or may not include oxygen). For example, the dielectric layers 52 may include an oxide such as silicon oxide, a nitride such as silicon nitride, or the like.

The metallization patterns and vias 54 and the top metal 56 may be formed using any suitable process, such as a single damascene process, a dual damascene process, a plating process, combinations thereof, or the like. An example of forming the metallization patterns and vias 54 and the top metal 56 by a damascene process includes etching dielectric layers 52 to form openings, depositing a conductive barrier layer into the openings, plating a metallic material such as copper or a copper alloy, and performing a planarization to remove the excess portions of the metallic material. In other embodiments, the formation of the dielectric layers 52, the metallization patterns and vias 54, and the top metal 56 may include forming the dielectric layer 52, patterning the dielectric layer 52 to form openings, forming a metal seed layer (not shown), forming a patterned plating mask (such as photoresist) to cover some portions of the metal seed layer, while leaving other portions exposed, plating the metallization patterns and vias 54 and the top metal 56, removing the plating mask, and etching undesirable portions of the metal seed layer. The metallization patterns and vias 54 and top metal 56 may be made of tungsten, cobalt, nickel, copper, silver, gold, aluminum, the like, or combinations thereof. In some embodiments, the top metal 56 is thicker than the metallization patterns 54, such as three times thicker, five times thicker, or any suitable thickness ratio between the metallization layers.

FIG. 7 further illustrates the formation of a passivation layer 58 over the dielectric layers 52 and the top metal 56. In some embodiments, the passivation layer 58 is formed of a same material as the dielectric layers 52. In some embodiments, the passivation layer 58 may be a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), or the like; the like; or a combination thereof. The passivation layer 58 may be formed, for example, by spin coating, lamination, chemical vapor deposition (CVD), or the like. The passivation layer 58 may have an upper surface that is level within process variations.

Although FIG. 7 illustrates the TSVs 44 directly connected to the interconnect structure 50, in some embodiments, one or more of the TSVs 44 may be directly connected to the active metallization patterns 26 in the interconnect structure 24.

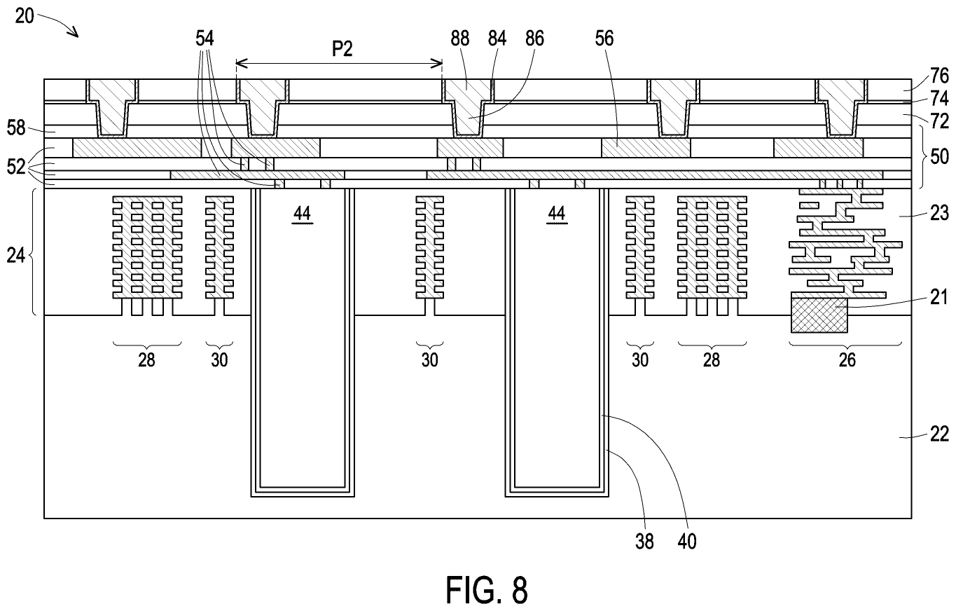

In FIG. 8, dielectric layers 72, 74, and 76 are formed over the passivation layer 58. Although FIG. 8 illustrates three dielectric layers 72, 74, and 76, more or fewer than three dielectric layers may be formed. The dielectric layer 72 is separated from the top metal structures 56 by the passivation layer 58. The dielectric layer 72 provides a planar top surface to form the dielectric layers 74 and 76 on and may be considered a planarization dielectric layer 72. The dielectric layer 74 may provide etch stop functions during subsequent formation of bond pads and bond vias and may be considered an etch stop layer 74. The dielectric layer 76 may provide dielectric bonding functions and may be considered a bonding dielectric layer 76.

In some embodiments, the dielectric layers 72, 74, and 76 are formed of a silicon-containing material. For example, the dielectric layers 72, 74, and 76 may include an oxide such as silicon oxide, a nitride such as silicon nitride, an oxynitride such as silicon oxynitride, the like, or a combination thereof.

FIG. 8 further illustrates the formation of bond pad vias 86 and bond pads 88 are formed in the dielectric layers 72, 74, and 76. The bond pad vias 86 and bond pads 88 are connected to the top metal 56. The bond pad vias 86 and bond pads 88 may be formed using any suitable process, such as a single damascene process, a dual damascene process, combinations thereof, or the like. A dual damascene process will be described.

In some embodiments, a photoresist (not shown) is formed and patterned on the dielectric layer. The photoresist may be formed by spin coating or the like and may be exposed to light for patterning. The pattern of the photoresist corresponds to openings for the bond pads 88. Further, the dielectric layer 76 is patterned to form the openings using the patterned photoresist as a mask with the patterning process stopping on the dielectric layer 74. The exposed portions of the dielectric layer 76 may be removed, such as by using an acceptable etching process, such as by wet and/or dry etching.

The photoresist is removed and may be removed by an acceptable ashing or stripping process, such as using an oxygen plasma or the like. Next, another photoresist (not shown) is formed and patterned on the patterned dielectric layer 76 and in the openings through the dielectric layer 76. The photoresist may be formed by spin coating or the like and may be exposed to light for patterning. The pattern of the photoresist corresponds to openings for the bond pad vias 86. The dielectric layers 74 and 72 are patterned to form the openings using the patterned photoresist as a mask with the patterning process exposing portions of the top metal 56. The exposed portions of the dielectric layers 74 and 72 may be removed, such as by using an acceptable etching process, such as by wet and/or dry etching.

The photoresist is removed and a barrier layer 84, the bond pad vias 86, and the bond pads 88 are formed in the openings. The barrier layer 84 may be formed in the openings prior to forming bond pad vias 86 and the bond pads 88. In some embodiments, the barrier layer 84 may comprise Ti, TiN, the like, or a combination thereof. The bond pad vias 86 and the bond pads 88 may be formed by similar processes and materials as the top metal 56 and vias 54 and the description is not repeated herein. The bond pads 88 may be formed of or comprise copper, for example. Adjacent bond pads 88 have a pitch P2. In some embodiments, the pitch P2 is as small as 3.0 μm. In some embodiments, the pitch P2 is in a range from 3.0 μm to 9.0 μm.

The top surfaces of the bond pads 88 are coplanar (within process variation) with the top surface of the uppermost dielectric layer 76. The planarization is achieved through a chemical mechanical polishing (CMP) process or a mechanical grinding process.

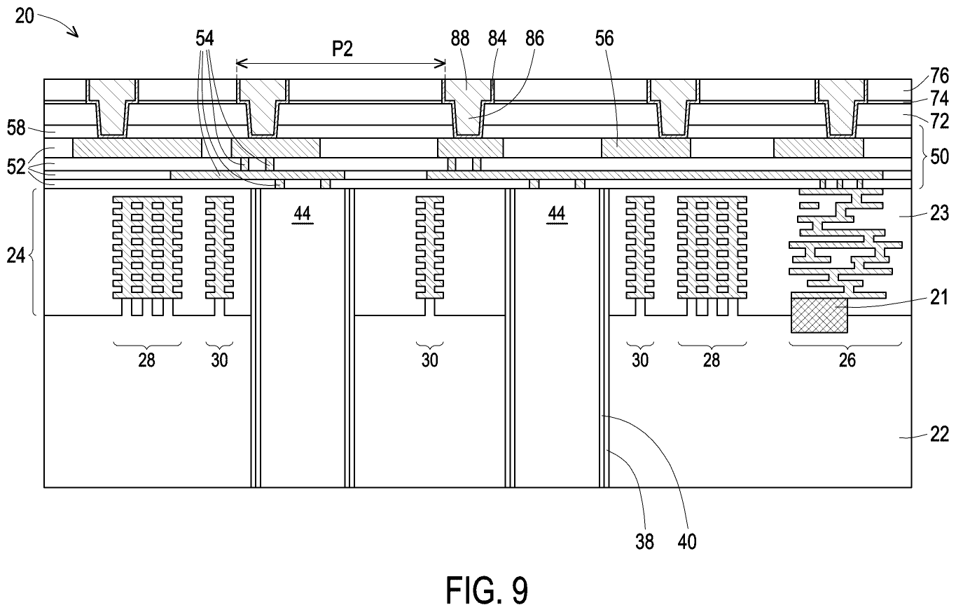

In FIG. 9, the integrated circuit die 20 is thinned by thinning the substrate 22 before a subsequent singulation process, if the singulation process is performed at all. The thinning may be performed through a planarization process such as a mechanical grinding process or a CMP process. The thinning process exposes the TSVs 44 and the liner 38. After thinning, the TSVs 44 provides electrical connection from a back side of the substrate 22 to a front side of the substrate 22 (e.g., the interconnects 24 and 50 and bond pads 88).

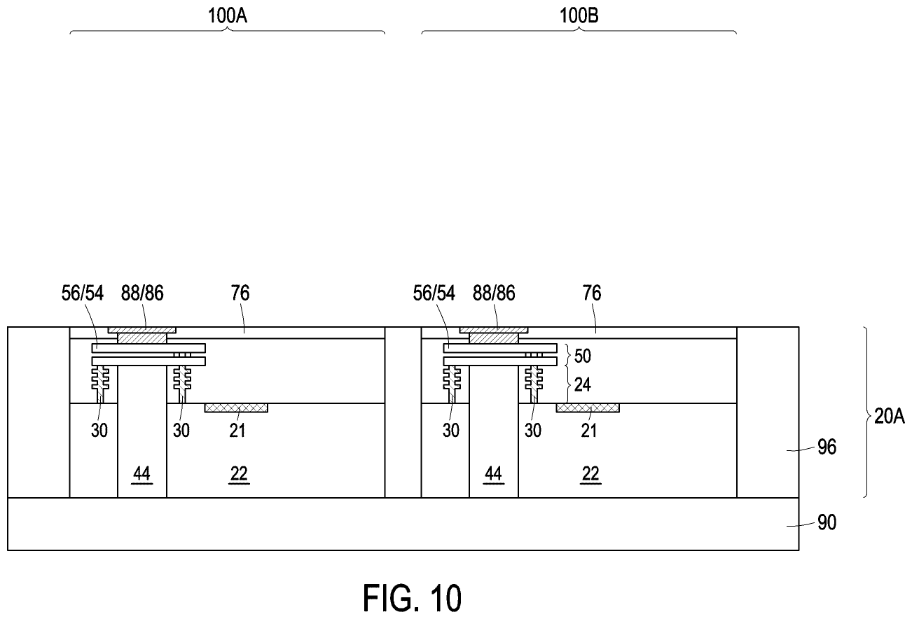

FIGS. 10, 11, 12, 13, 14, 15, 16, 17, 18, 19, 20, and 21 illustrate cross-sectional views of intermediate stages in the formation of stacked packages 100 in accordance with some embodiments.

In FIG. 10, multiple integrated circuit dies 20A are attached to a carrier substrate 90. The integrated circuit dies 20A are similar to the integrated circuit dies 20 described above and the description is not repeated herein. For example, the integrated circuit dies 20 after the processing of FIG. 9 are attached to the carrier substrate 90. In some embodiments, the substrate thinning step of FIG. 9 is omitted and the unthinned substrates (e.g., TSVs 44 are not exposed) are attached to the carrier substrate 90.

As illustrated in FIG. 10, an integrated circuit die 20A is placed in each of package regions 100A and 100B. Although FIGS. 10 through 21 two package regions 100a and 100B, more or less package regions are contemplated. The stacked packages are formed in a wafer form, which may include different package regions (e.g., 100A and 100B) that are singulated in subsequent steps to form a plurality of stacked packages.

The carrier substrate 90 may be a glass carrier substrate, a ceramic carrier substrate, or the like. The carrier substrate 90 may be a wafer, such that multiple structures 20A can be attached to the carrier substrate 90 simultaneously. The structures 20A can be attached by an adhesive film (not shown) between the structure 20 and the carrier substrate 90.

In some embodiments, a release layer (not shown) is formed on the carrier substrate 90, and the structure 20A and adhesive film, if present, are attached to the release layer. The release layer may be formed of a polymer-based material, which may be removed along with the carrier substrate 90 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer may be an ultra-violet (UV) glue, which loses its adhesive property when exposed to UV lights. The release layer may be dispensed as a liquid and cured, may be a laminate film laminated onto the carrier substrate 90, or may be the like. The top surface of the release layer may be leveled and be substantially planar within process variations.

Further in FIG. 10, a gap-filling process is performed to encapsulate the dies 20A in an encapsulant 96. After formation, the encapsulant 96 encapsulates the dies 20A. The encapsulant 96 may comprise an oxide. Alternatively, the encapsulant 96 may be a molding compound, a molding underfill, a resin, an epoxy, or the like. The encapsulant 96 may be applied by compression molding, transfer molding, or the like, and may be applied in liquid or semi-liquid form and then subsequently cured.

After the encapsulant 96 is deposited, a planarization process is performed to level front-side surfaces of the integrated circuit dies 20A with the top surface of the encapsulant 96 and to expose the bond pads 88 and the dielectric layer 76. Surfaces of the bond pads 88, the dielectric layers 76, and the encapsulant 96 are coplanar after the planarization process within process variations. The planarization process may be, for example, a chemical-mechanical polish (CMP), a grinding process, or the like. In some embodiments, the planarization may be omitted, for example, if the bond pads 88 and dielectric layer 76 are already exposed.

The integrated circuit dies 20A may be referred to as a layer of dies in the stacked package. For example, the dies 20A may be referred to as the first layer or bottom layer of the stacked package.

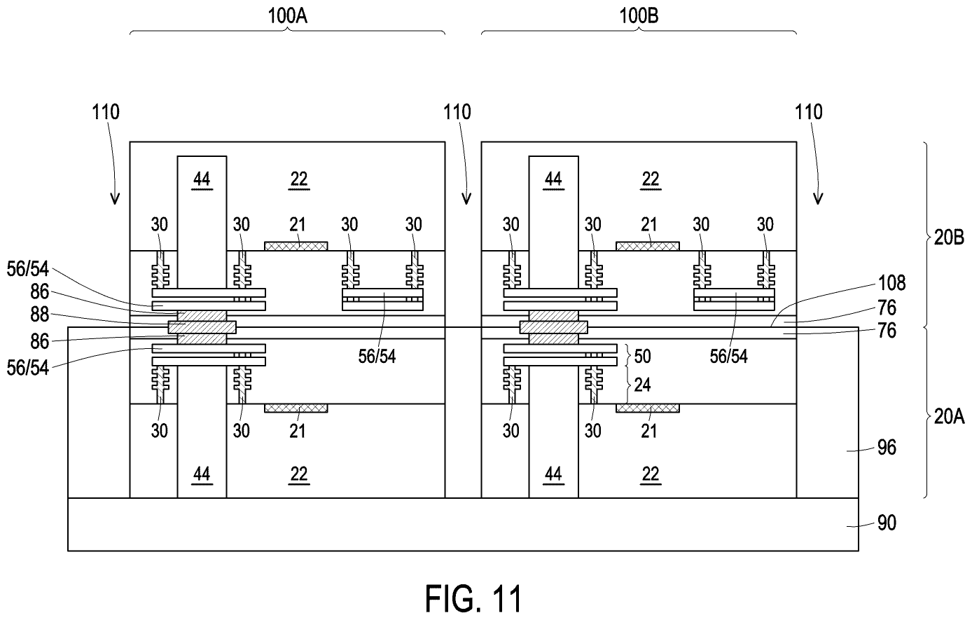

In FIG. 11, a next layer of integrated circuit dies 20B is bonded to the first layer of integrated circuit dies 20A. The bonding of the integrated circuit dies 20B to the integrated circuit dies 20A may be achieved through direct bonding, in which both metal-to-metal direct bonding (between the respective bond pads 88) and dielectric-to-dielectric bonding (such as Si—O—Si bonding between surface dielectric layers 76 of the integrated circuit dies 20A and 20B) are formed. In this embodiment, a single die 20B is bonded to a single die 20A in each of the package regions 100A and 100B. However, in other embodiments, there may be a plurality of dies 20B bonded to the same die 20A. The plurality of dies 20B bonded to the same dies 20A may be identical to, or different from, each other to form a homogenous or a heterogeneous structure.

The dies 20A are disposed face up such that the front sides of the dies 20A face the dies 20B and the back sides of the dies 20A face away from the dies 20B. The dies 20A are bonded to the dies 20B at an interface 108. As illustrated by FIG. 11, the direct bonding process directly bonds the topmost dielectric layers 76 of the dies 20B to the topmost dielectric layers 76 of the dies 20A at the interface 108 through fusion bonding. In an embodiment, the bond between the topmost dielectric layers 76 of the dies 20B and the topmost dielectric layers 76 of the dies 20A may be oxide-to-oxide bonds. The direct bonding process further directly bonds the bond pads 88 of the dies 20A to the bond pads 88 of the dies 20B at the interface 108 through direct metal-to-metal bonding. Thus, electrical connection between the dies 20A and the dies 20B is provided by the physical connection of the bond pads 88.

As an example, the direct bonding process starts with aligning the dies 20B with the respective dies 20A, for example, by aligning the bond pads 88. When the dies 20A and the dies 20B are aligned, the bond pads 88 may overlap with the corresponding bond pads 88. Next, the direct bonding includes a pre-bonding step, during which the dies 20B is put in contact with the dies 20B. The direct bonding process continues with performing an anneal, for example, at a temperature between 150° C. and 400° C. for a duration between 0.5 hours and 3 hours, so that the copper in the bond pads 88 inter-diffuses to each other, and hence the direct metal-to-metal bonding is formed. The bonding of the layer of dies 20B to the layer of dies 20A forms gaps 110 between adjacent dies 20B.

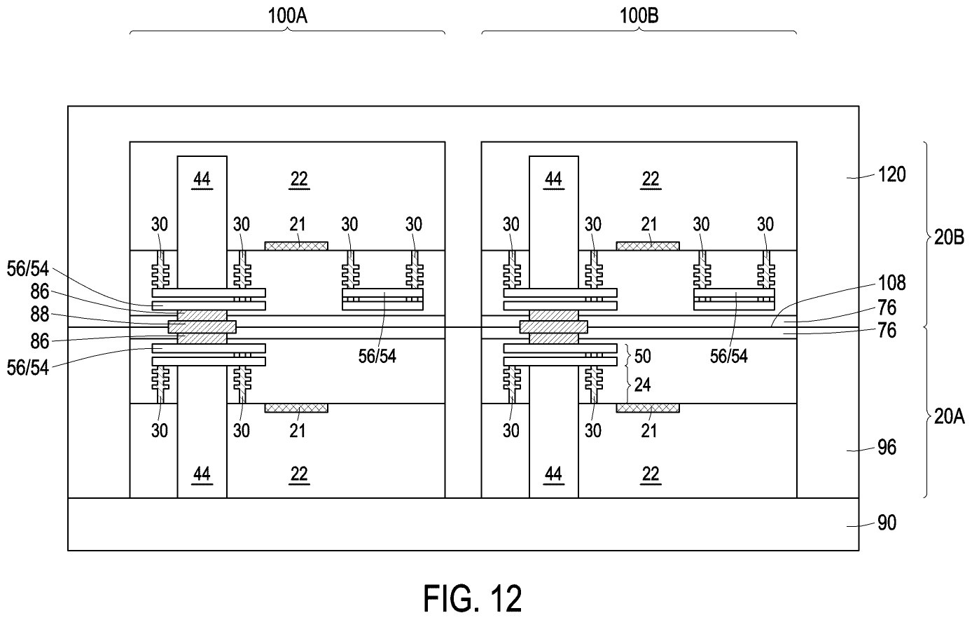

Next, as shown in FIG. 12, a gap-filling process is performed to fill the gaps 110 and encapsulate the dies 20B in an encapsulant 120. After formation, the encapsulant 120 encapsulates the dies 20B and is on the encapsulant 96. The encapsulant 120 be similar to the encapsulant 96 described above and the description is not repeated herein. After formation, the encapsulant 120 encapsulates the dies 20B.

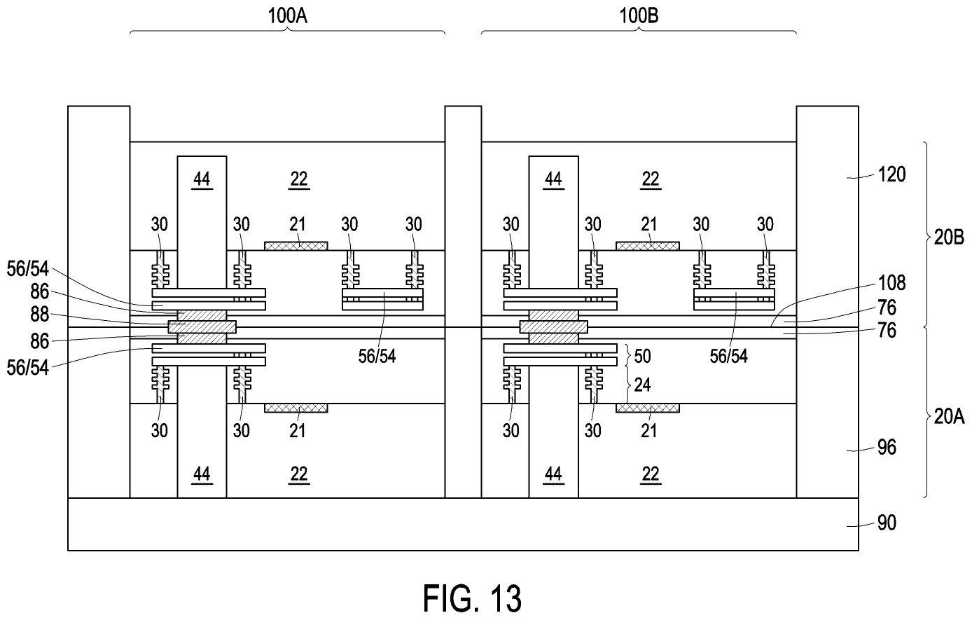

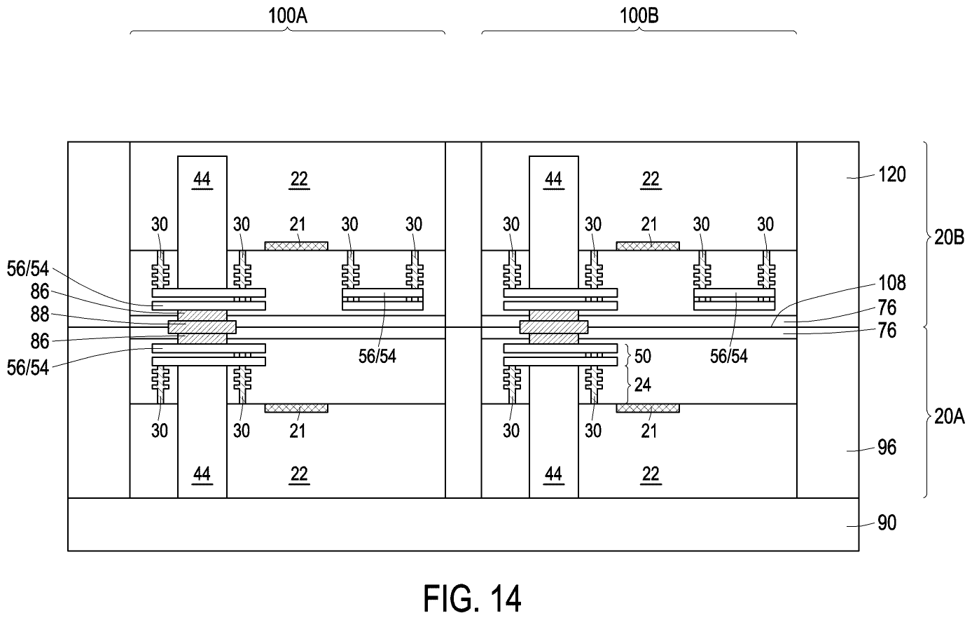

In FIGS. 13 and 14, the encapsulant 120 is removed from over the back sides of the dies 20B and planarized. In FIG. 13, the encapsulant is removed from the back sides of the dies 20B to expose the back sides of the dies 20B. This step may include a lithography and etching process to pattern the encapsulant 120.

In FIG. 14, a planarization process is performed to level back side surfaces of the integrated circuit dies 20B with the top surface of the encapsulant 120 and to ensure the back sides of the dies 20B are exposed. Surfaces of the substrates 22 of the dies 20B and the encapsulant 120 are coplanar after the planarization process within process variations. The planarization process may be, for example, a CMP, a grinding process, or the like. In some embodiments, the planarization may be omitted, for example, if the encapsulant 120 and the back sides of the dies 20B are already coplanar.

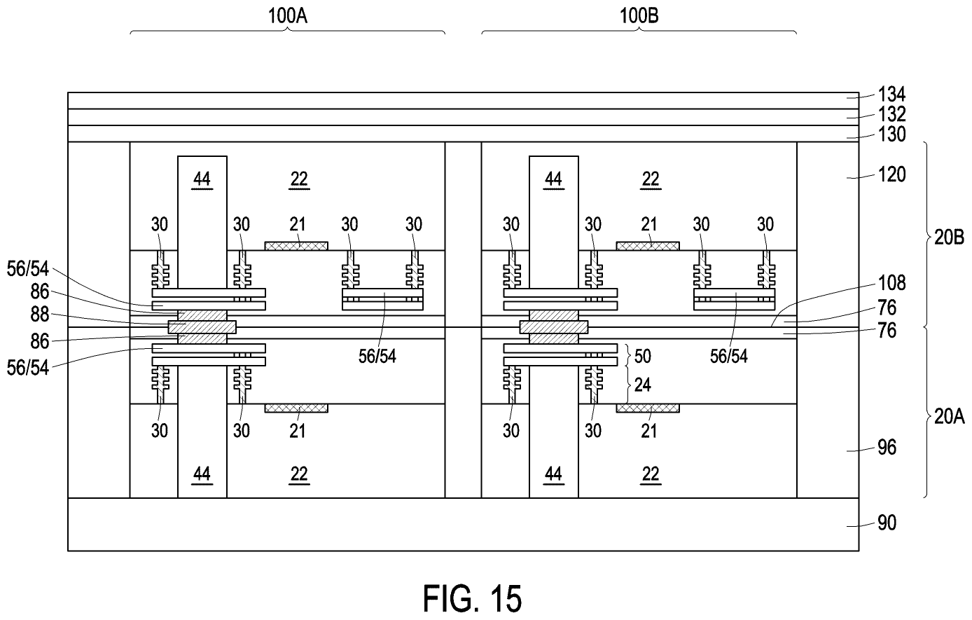

In FIG. 15, a stack of layers 130, 132, and 134 are formed over the back sides of the dies 20B and the encapsulant 120. In some embodiments, the stack of layers include a stop layer 130 on the backsides of the dies 20B and the encapsulant 120, a dielectric layer 132 on the stop layer 130, and a mask layer 134 on the dielectric layer 132. In some embodiments, the stop layer 130 and the dielectric layer 132 could be omitted and only the mask layer 134 is present.

In some embodiments, the stop layer 130, such as a chemical mechanical polishing (CMP) stop layer 130 is deposited over the back sides of the dies 20B and the encapsulant 120. The CMP stop layer 130 may be used to prevent a subsequent CMP process from removing too much material by being resistant to the subsequent CMP process and/or by providing a detectable stopping point for the subsequent CMP process. In some embodiments, the CMP stop layer 130 may comprise one or more layers of dielectric materials. Suitable dielectric materials may include oxides (such as silicon oxide, aluminum oxide, or the like), nitrides (such as SiN, or the like), oxynitrides (such as SiON, or the like), oxycarbides (such as SiOC, or the like), carbonitrides (such as SiCN, or the like), carbides (such as SiC, or the like), combinations thereof, or the like, and may be formed using spin-on coating, CVD, PECVD, ALD, the like, or a combination thereof.

In some embodiments, the dielectric layer 132 is deposited over CMP stop layer 130. The dielectric layer 132 may be used to transfer the pattern of the mask layer 134 to underlying layers. In some embodiments, the dielectric layer 132 may comprise one or more layers of dielectric materials. Suitable dielectric materials may include oxides (such as silicon oxide, aluminum oxide, or the like), nitrides (such as SiN, or the like), oxynitrides (such as SiON, or the like), combinations thereof, or the like, and may be formed using spin-on coating, CVD, PECVD, ALD, the like, or a combination thereof.

In some embodiments, the mask layer 134 is formed on the dielectric layer 132, if present. In some embodiments, the mask layer 134 is a photoresist and may be formed by spin coating or the like.

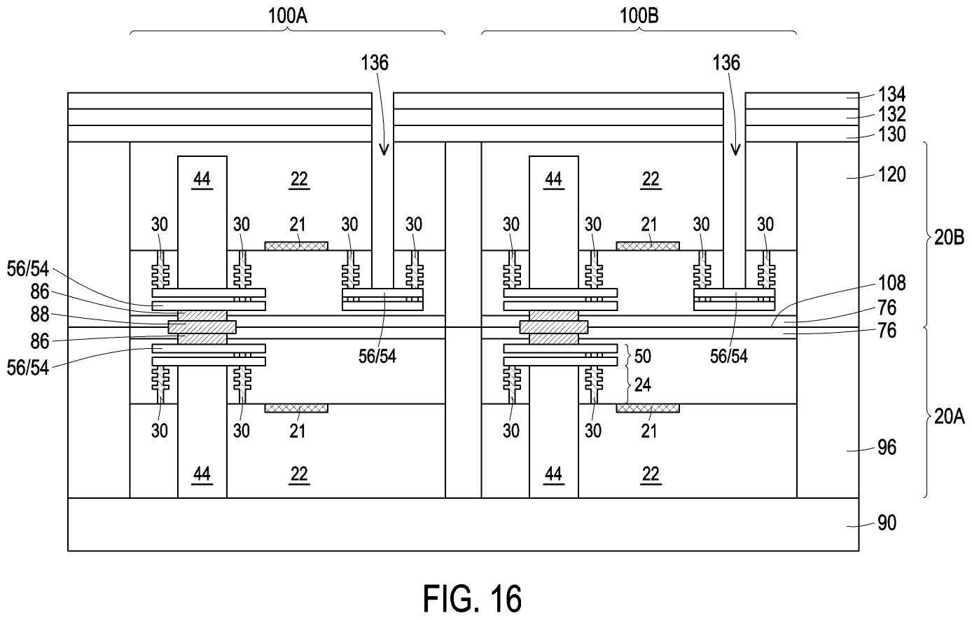

In FIG. 16, the mask layer 134, the dielectric layer 132, the CMP stop layer 130, the substrates 22 of the dies 20B, and the interconnect structures 24 of the dies 20B are patterned. This patterned process exposes metallization patterns in the interconnect structure of the dies 20B, such as the top metal 56 of the dies 20B.

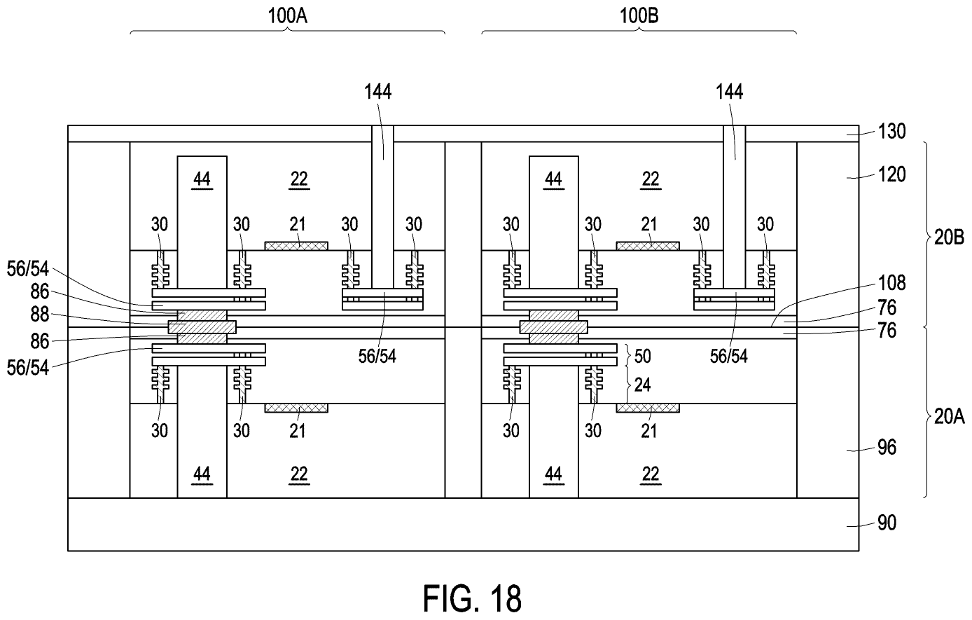

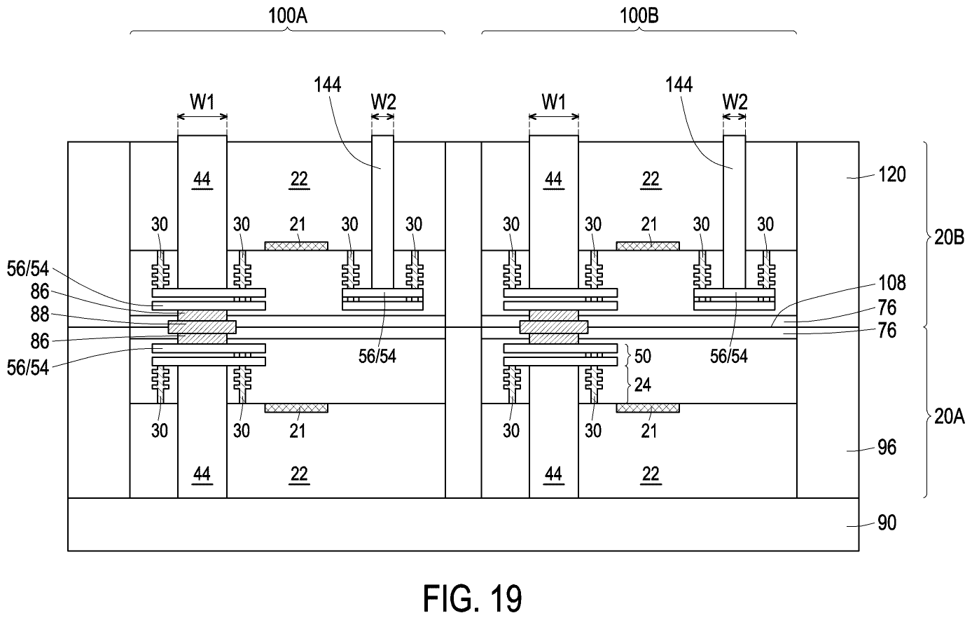

The mask layer 134 may be a photoresist and may be exposed to light for patterning. The pattern of the mask layer 134 corresponds to the subsequently formed through substrate via (TSV) 144 (see, e.g., FIGS. 18 and 19). The patterning forms at least one opening through the mask layer 134 to expose the underlying layer.

Further in FIG. 16, the remaining mask 134 is used as a mask during an etching process to remove exposed and underlying portions of the dielectric layer 132, the CMP stop layer 130, the substrates 22, and the dielectric layers 23 of the interconnect structures 24 forming openings 136. A single etch process may be used to etch openings 136 through the dielectric layer 132, the CMP stop layer 130, the substrates 22, and the dielectric layers 23 of the interconnect structures 24. In some embodiments, multiple etch processes are used to form the openings 136. For example, different etch processes may be used to etch through the different respective layers/structures. In some embodiments, the openings 136 are formed with a plasma dry etch process, and a reactive ion etch (RIE) process, such as a deep RIE (DRIE) process. In some embodiments, the DRIE process includes etch cycle(s) and passivation cycle(s) with the etch cycle(s) using, for example, SF₆, and the passivation cycle(s) using, for example, C₄F₈. The utilization of a DRIE process with the passivation cycle(s) and the etch cycle(s) enables a highly anisotropic etching process. In some embodiments, the etch process(es) may be any acceptable etching process, such as by wet or dry etching.

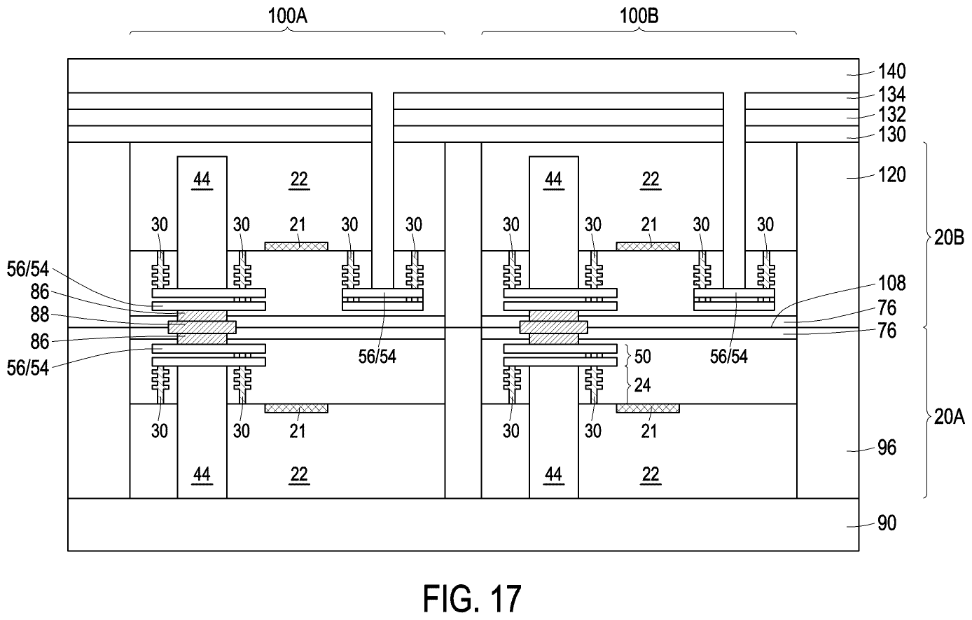

In FIG. 17, conductive material 140 is formed in the openings 136 and over the mask 134. In some embodiments, the mask 134 is removed before the conductive material 140 is formed.

Prior to the formation of the conductive material 140, a liner layer (not shown) and a seed layer (not shown) may be formed in the openings 136. The liner layer may be conformally deposited on the mask layer 134 and on bottom surfaces and sidewalls of the openings 136. In some embodiments, the liner layer includes one or more layers of dielectric materials and may be used to physically and electrically isolate the subsequently formed through vias from the substrate 22. Suitable dielectric materials may include oxides (such as silicon oxide, aluminum oxide, or the like), nitrides (such as SiN, or the like), oxynitrides (such as SiON, or the like), combinations thereof, or the like. The liner layer may be formed using CVD, PECVD, ALD, the like, or a combination thereof.

In a subsequent step, the seed layer is formed over liner layer. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. In some embodiments, a barrier layer (not shown) may be formed on the liner layer prior to forming the seed layer. The barrier layer may comprise Ti, TiN, the like, or a combination thereof.

Further in FIG. 17, the conductive material 140 is formed on the seed layer and fills the openings 136. The conductive material 140 may be formed by plating, such as electroplating including electrochemical plating, electroless plating, or the like. The conductive material may comprise a metal, like copper, titanium, tungsten, aluminum, or the like.

After the conductive material 140 is formed, an anneal process is then performed. The anneal process may be performed to prevent subsequent extrusion of the conductive material of the TSV 144 (sometime referred to as TSV pumping). The TSV pumping is caused by a coefficient of thermal expansion (CTE) mismatch between the conductive material 140 and the substrate 22 and can cause damage to structures (e.g., metallization patterns) underlying the TSVs.

Following the anneal process, a planarization process is performed to remove portions of the conductive material 140, the seed layer, the liner layer, the mask layer 134, and the dielectric layer 132 outside the openings 136 to form TSVs 144 as illustrated in FIG. 18. Top surfaces of the TSV 144 and the CMP stop layer 130 are coplanar after the planarization process within process variations. The planarization process may be, for example, a CMP, a grinding process, or the like.

In FIG. 19, the CMP stop layer 130 is removed and the substrates 22 are thinned to expose the TSVs 44. The CMP stop layer 130 and the thinning process may be performed by a planarixation process, such as, a CMP, a grinding process, or the like. After the planarization process, surfaces of the TSVs 144, the TSVs 44, and the back side surfaces of the substrates 22 are coplanar within process variations. In some embodiments, the surfaces of the TSVs 144 and the TSVs 44 protrude from the back side surfaces of the substrates 22 after the thinning process.

In some embodiments, the upper portion of the TSVs 144 (formed in the substrates 22) has a greater width than the lower portion of the TSVs 144 (formed in interconnect structures 24). In some embodiments, the width of the TSVs 144 is constant through the interconnects 24 and the substrates 22. In some embodiments, the TSVs 144 are formed to have a width W2. In some embodiments, the width W2 of the TSVs 144 is less than the width W1 of the TSVs 44. In some embodiments, the width W2 is as small as 0.1 μm. In some embodiments, the ratio of the widths W1/W2 is in a range from 1.5 to 70.

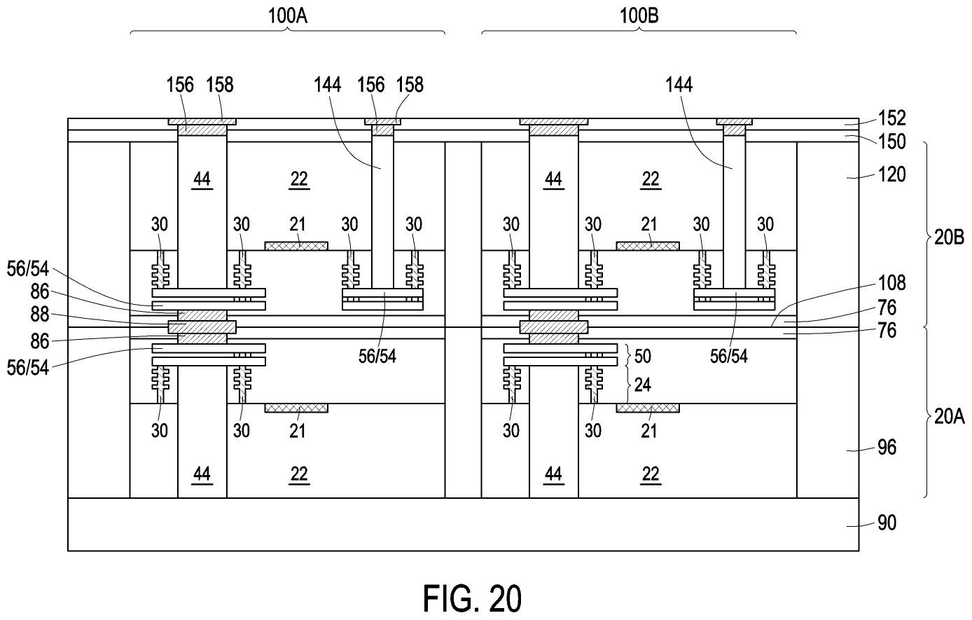

In FIG. 20, back side bond pad structures are formed. Dielectric layers 150 and 152 and bond pad vias 156 and bond pads 158 are formed on and over the dies 20B and the TSVs 44 and 144. The dielectric layers 150 and 152 may be similar to the dielectric layers 72, 74, and 76 described above the description is not repeated herein. The bond pad vias 156 and the bond pads 158 may be similar to the bond pad vias 86 and the bond pads 88 described above and the description is not repeated herein. The back side bond pad structures may include some redistribution layers.

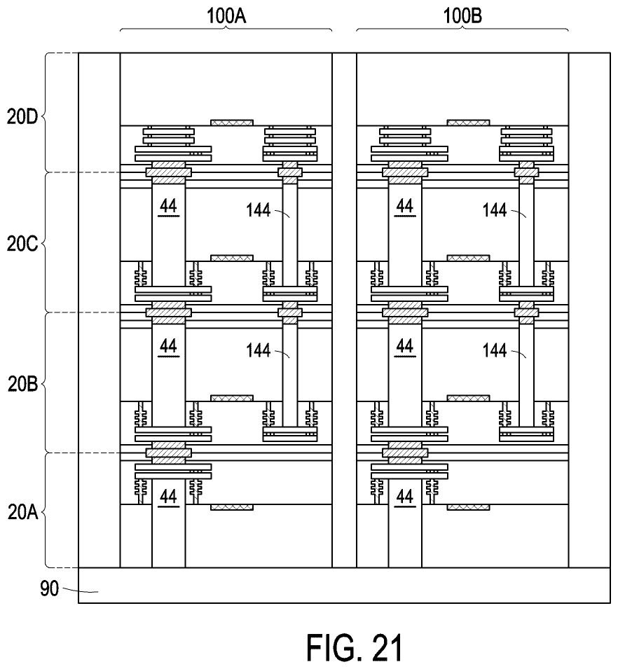

In FIG. 21, the previously described steps of bonding a new layer of dies 20 is repeated two more times for dies 20C and dies 20D. These die layers may be formed as described above the description is not repeated herein. The dies 20D may be referred to as a top die layer and the dies 20D in this layer may not include TSVs. As illustrated, the dies 20A (e.g., the bottom dies 20A) do not include the TSVs 144, but in some embodiments, the dies 20A do include the TSVs 144.

The structure of FIG. 21 may undergo further processing, such as removing the carrier substrate 90, forming conductive connectors on the TSVs 44 in the dies 20A, and singulating the stacked packages 100 along the scribe lines between the regions 100A and 100B. The conductive connectors (not shown) allow for external connection to the singulated stacked packages 100.

The larger TSVs 44 are optimized for power delivery and the smaller TSVs 144 are used for signal communication between the components of the stack packages 100. For example, the larger TSVs 44 can be power or ground lines for the stacked packages 100 and the smaller TSVs 144 can be signal lines between different components of the stacked package 100. By incorporating different TSV CDs in a single solution for both power and signal delivery, the disclosed embodiments allow for multi-stacking beyond just two-tier stacking and provides a more flexible design. In addition, the use of the optimized smaller TSVs for the signal delivery reduces the TSV area overhead.

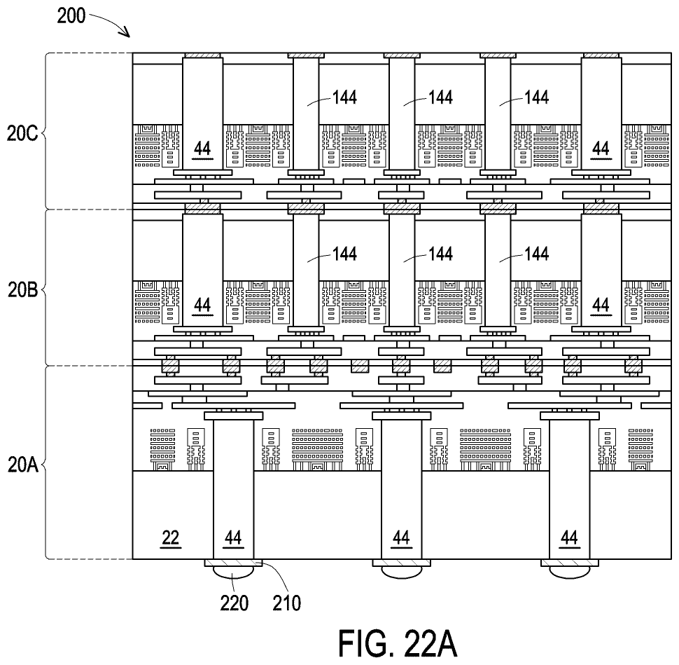

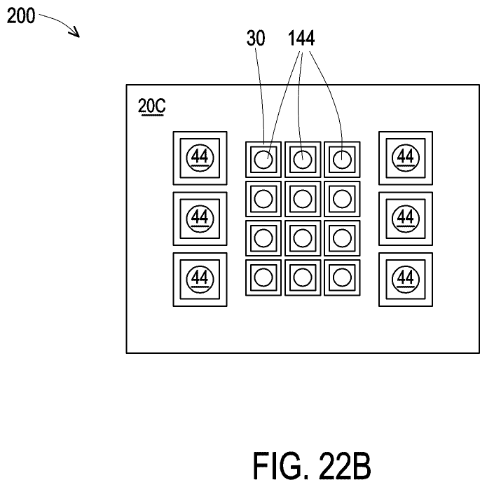

FIGS. 22A, 22B, 23A, 23B, 24A, 24B, 25, 26, 27A, 27B, 28A, and 28B illustrate cross-sectional views and plan views of various packages in accordance with some embodiments.

FIGS. 22A and 22B illustrate a cross-sectional view and a plan view of a stacked package 200 in accordance with some embodiments. This embodiment is similar to the embodiment described in FIGS. 1-21 and the description is not repeated herein. In this embodiment, the TSVs 144 are clustered in a central area of the layers 20B and 20C and the TSVs 44 are around that cluster. Further, in this embodiment, the layers 20A, 20B, and 20C are wafer-scale structures and not die-scale structures. These wafers have been direct bonded together to form the stacked package 200. Although this embodiment has three layers of structures, more or less layers are contemplated within the scope of this disclosure. For example, one or more layers of wafers could be bonded to the wafer 20C.

In addition, FIG. 22A illustrates under-bump metallizations (UBMs) 210 and conductive connectors 220 on the wafer 20A. They are formed for external connection to stacked package 200. The UBMs 210 are electrically coupled to the TSVs 44 in the wafer 20A.

In accordance with some embodiments of the present disclosure, the UBMs 210 are formed through plating processes, wherein each of the UBMs includes a seed layer (not shown) and a plated metallic material over the seed layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs. The patterning forms openings through the photoresist to expose the seed layer. A conductive material is formed in the openings of the photoresist and on the exposed portions of the seed layer. The conductive material may be formed by plating, such as electroplating or electroless plating, or the like. The seed layer and the plated metallic material may be formed of the same material or different materials. The conductive material may be a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet and/or dry etching. The remaining portions of the seed layer and conductive material form the UBMs.

Conductive connectors 220 are formed on the UBMs 210. The conductive connectors 220 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 220 may include a conductive material such as solder, copper, aluminum, gold, nickel, silver, palladium, tin, the like, or a combination thereof. In some embodiments, the conductive connectors 220 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 220 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

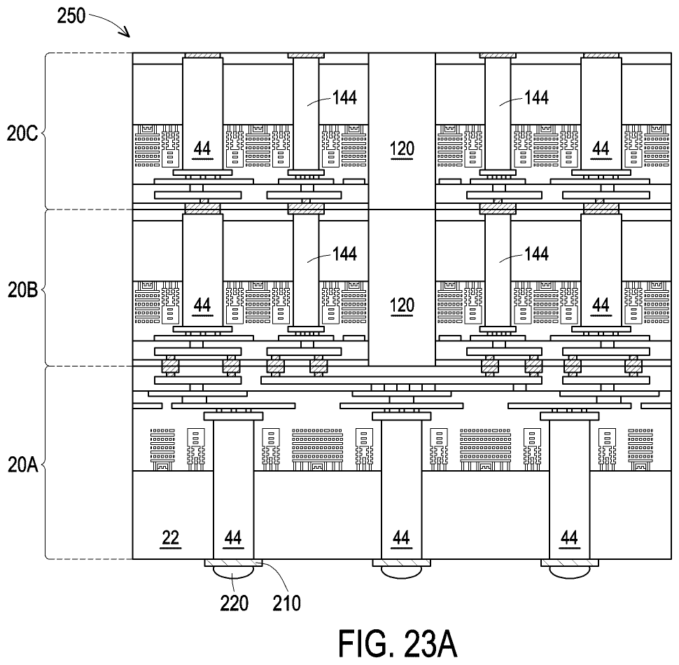

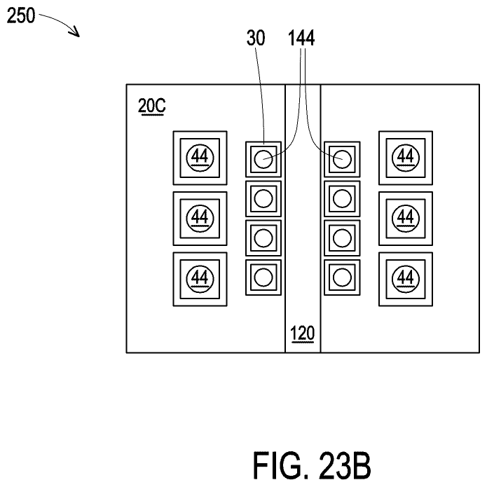

FIGS. 23A and 23B illustrate a cross-sectional view and a plan view of a stacked package 250 in accordance with some embodiments. This embodiment is similar to the embodiment in FIGS. 22A and 22B and the description is not repeated herein. In this embodiment, the layers 20B and 20C are die-scale structures and the layer 20A is a wafer-scale structure. For example, FIGS. 23A and 23B may be referred to as a chip-on-chip-on-wafer structure 250. Although this embodiment has three layers of structures, more or less layers are contemplated within the scope of this disclosure. For example, one or more layers of wafers/dies could be bonded to the dies 20C.

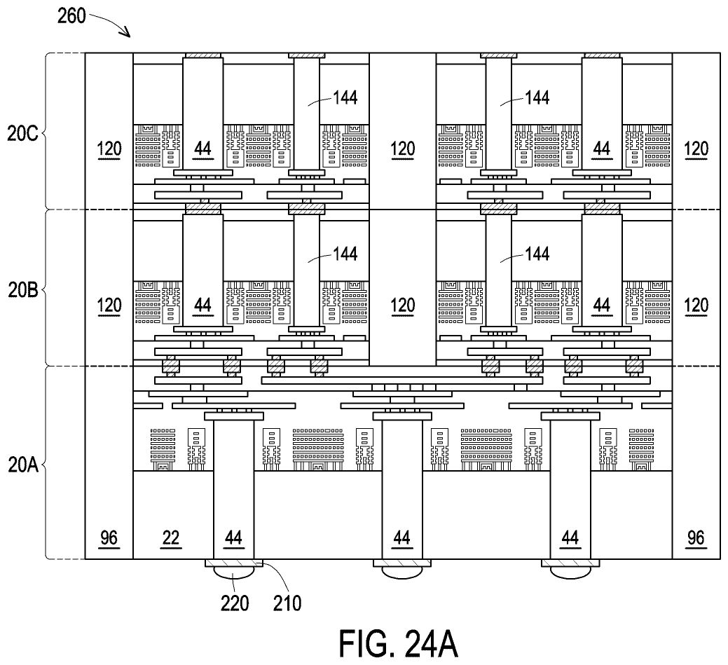

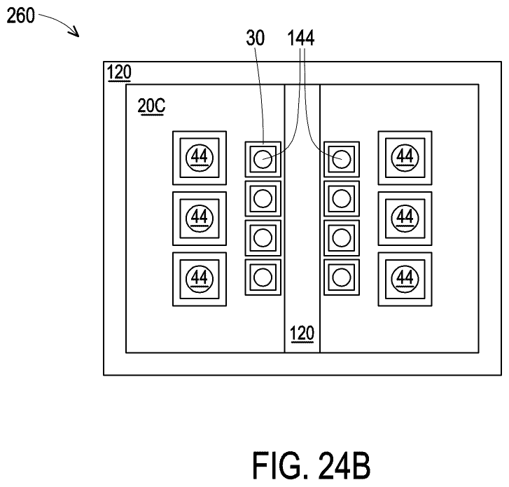

FIGS. 24A and 24B illustrate a cross-sectional view and a plan view of a stacked package 260 in accordance with some embodiments. This embodiment is similar to the embodiment in FIGS. 23A and 23B and the description is not repeated herein. In this embodiment, all of the layers 20A, 20B, and 20C are die-scale structures. For example, FIGS. 24A and 24B may be referred to as a chip-on-chip-on-chip structure 260. Although this embodiment has three layers of structures, more or less layers are contemplated within the scope of this disclosure. For example, one or more layers of wafers/dies could be bonded to the dies 20C.

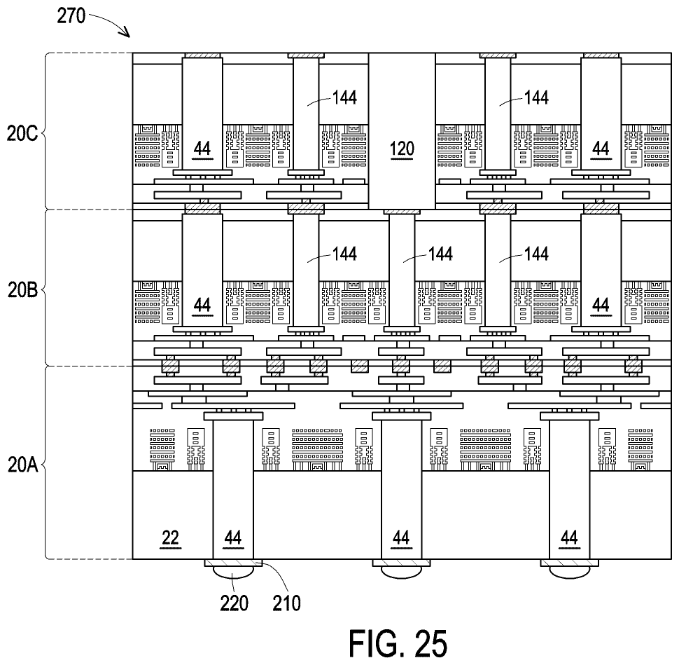

FIG. 25 illustrate a cross-sectional view of a stacked package 270 in accordance with some embodiments. This embodiment is similar to the embodiment in FIGS. 23A and 23B and the description is not repeated herein. In this embodiment, the layer 20C are die-scale structures and the layers 20A and 20B are wafer-scale structures. For example, FIG. 25 may be referred to as a chip-on-wafer-on-wafer structure 270. Although this embodiment has three layers of structures, more or less layers are contemplated within the scope of this disclosure. For example, one or more layers of wafers/dies could be bonded to the dies 20C.

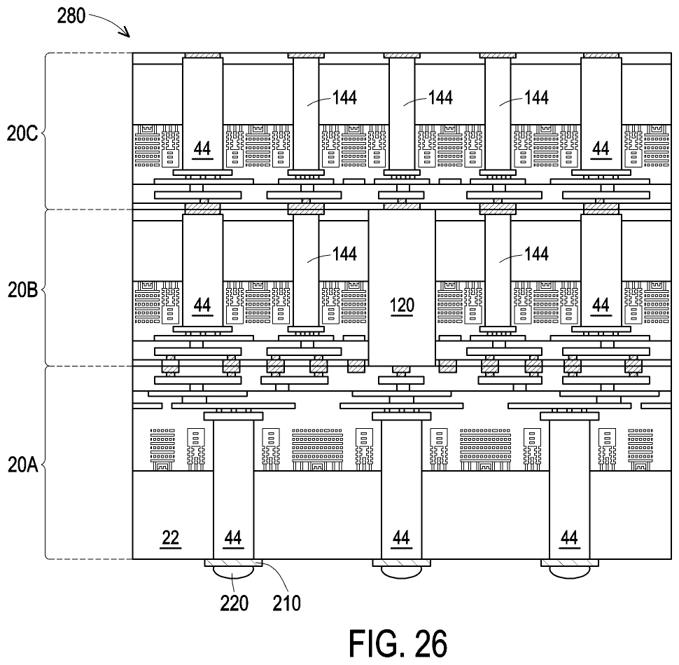

FIG. 26 illustrate a cross-sectional view of a stacked package 280 in accordance with some embodiments. This embodiment is similar to the embodiment in FIG. 25 and the description is not repeated herein. In this embodiment, the layers 20A and 20C are wafer-scale structures and the layer 20B are die-scale structures. For example, FIG. 26 may be referred to as a wafer-on-chip-on-wafer structure 280. Although this embodiment has three layers of structures, more or less layers are contemplated within the scope of this disclosure. For example, one or more layers of wafers/dies could be bonded to the wafer 20C.

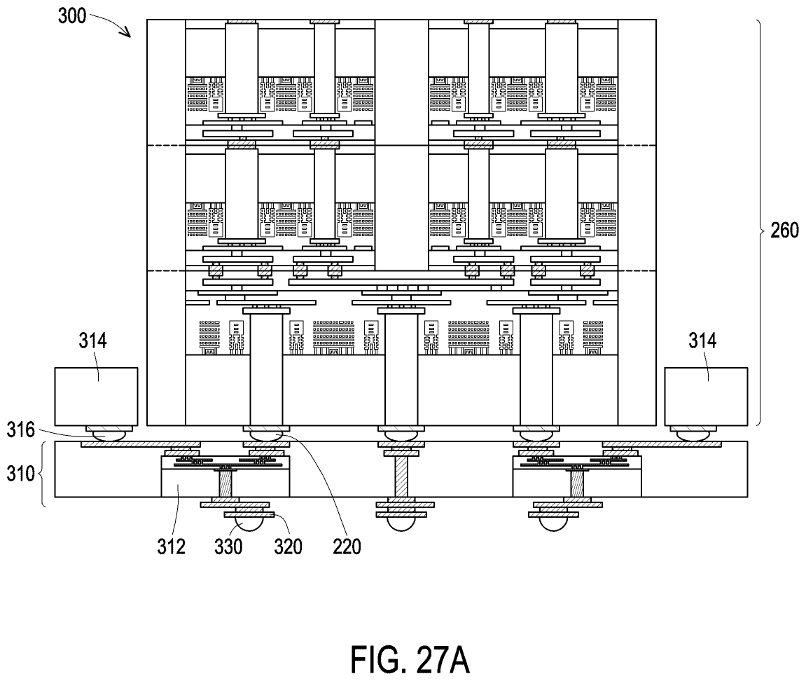

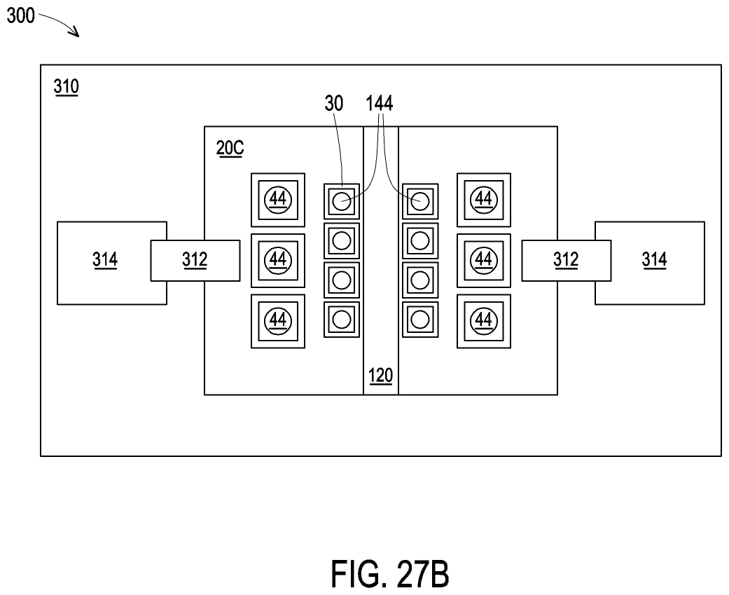

FIGS. 27A and 27B illustrate a cross-sectional view and a plan view of a stacked package 300 in accordance with some embodiments. This embodiment is similar to the embodiment in FIGS. 24A and 24B and the description is not repeated herein. In this embodiment, the stacked package 260 from FIGS. 24A and 24B is attached to an interposer 310 using the conductive connectors 220. Although this embodiment has three layers of structures in the stacked package 260, more or less layers are contemplated within the scope of this disclosure. Although this embodiment illustrates the stacked package 260, any of the stacked packages from FIGS. 21 through 26 could be applied to this embodiment.

The interposer 310 may be, for example, an organic interposer, a redistribution structure, or the like. The interposer 310 may include a plurality of redistribution layers formed in a plurality of dielectric layers (not individually illustrated). The redistribution layers may include conductive lines, conductive vias, conductive pads, or the like. The redistribution layers may be formed of a conductive material, such as a metal, such as copper, cobalt, aluminum, gold, combinations thereof, or the like. The interposer 310 may also include other conductive features, such as metallization patterns, through vias, or the like. In some embodiments, the dielectric layers may comprise a polymer such as polybenzoxazole (PBO), polyimide, a benzocyclobuten (BCB) based polymer, or the like. In other embodiments, the dielectric layers may comprise other suitable dielectric materials, such as silicon oxide or the like. The redistribution layers may be formed using any suitable process, such as deposition, plating, damascene, dual damascene, or the like. In some embodiments, the interposer 310 is substantially free of active and passive devices. In some cases, the use of an interposer 310 may reduce manufacturing cost and package size. In some embodiments, dies 314 are attached to the interposer 310 with conductive connectors 316. The conductive connectors 316 may be similar to the conductive connectors 220 described above and the description is not repeated herein.

In some embodiments, the dies 314 may be chips, chiplets, surface mount devices, or the like. The dies 314 may include a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. In some embodiments, the dies 314 are passive devices. In some embodiments, the dies 314 are bonded to the interposer 310 with the conductive connectors 316.

In some embodiments, the interposer 310 includes local interconnects 312. The local interconnects 312 may be, for example, chips, chiplets, local silicon interconnects (LSIs), interconnect structures, or the like, that provide additional electrical interconnections within the interposer 310. For example, the local interconnects 312 may provide electrical connections (e.g., bridging connections) between adjacent semiconductor devices, such as between stacked package 260 and the dies 314. Accordingly, the conductive connectors 316 and 220 may be electrically coupled to the local interconnects 312. The local interconnects 312 may include conductive features (e.g., conductive lines, vias, pads, or the like) formed in dielectric layers. The conductive features may be formed using suitable techniques, such as damascene, dual damascene, or the like. For example, in some cases, a local interconnect 312 may comprise an interconnect structure on a substrate, which may have through-substrate vias (TSVs) within, though other local interconnects 312 are possible. The local interconnects 312 may or may not include passive devices or active devices. The local interconnects 312 shown in FIGS. 27A and 27B are illustrative examples, and local interconnects 312 may have a different arrangement, number, configuration, or size than shown.

The interposer 310 further includes redistribution structures 320 and conductive connectors 330 to allow for external connection to the interposer 310 and attached components. In some embodiments, the redistribution structures 320 include redistribution layers and/or UBMs as previously described and the description is not repeated herein. The conductive connectors 330 may be similar to the conductive connectors 220 described above and the description is not repeated herein.

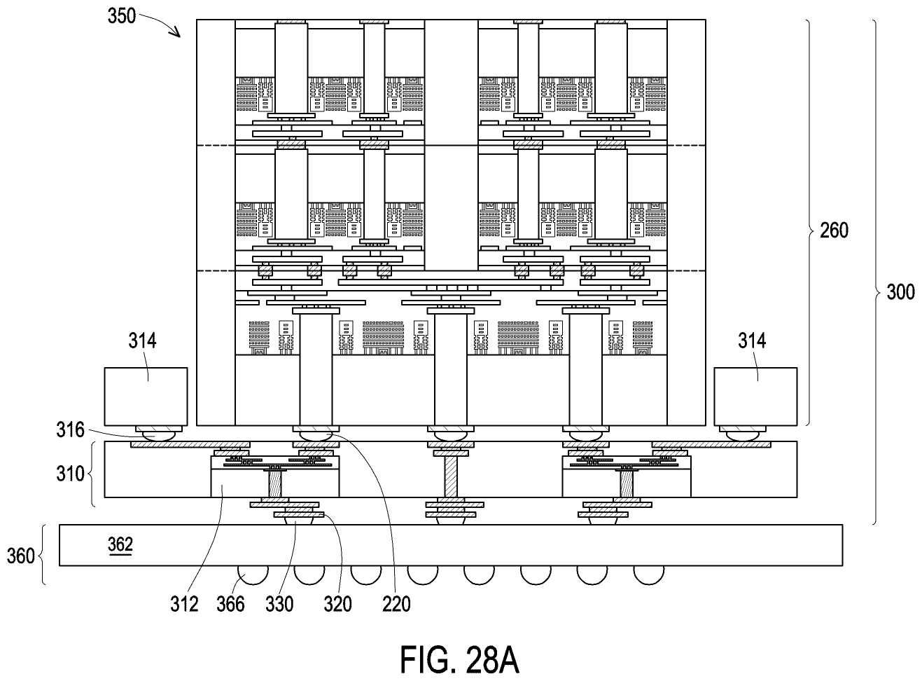

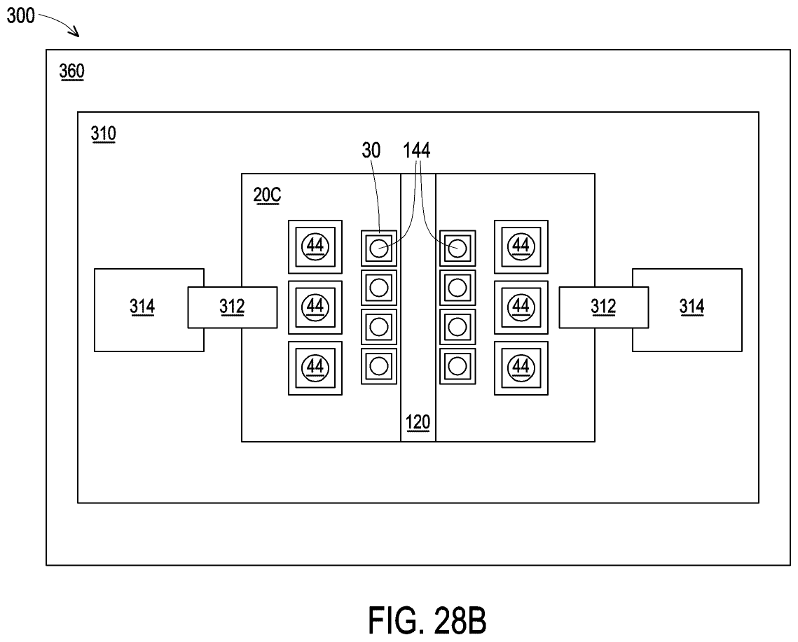

FIGS. 28A and 28B illustrate a cross-sectional view and a plan view of a stacked package 350 in accordance with some embodiments. This embodiment is similar to the embodiment in FIGS. 27A and 27B and the description is not repeated herein. In this embodiment, the package 300 from FIGS. 27A and 27B is attached to a substrate 360 using the conductive connectors 330. Although this embodiment illustrates the stacked package 260, any of the stacked packages from FIGS. 21 through 26 could be applied to this embodiment.

In FIGS. 28A and 28B, the package component of FIGS. 27A and 27B is attached to the substrate 360, such as a package substrate 360, using the conductive connectors 330 to form a package structure 350. The package substrate 360 includes a substrate core 362, which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 362 may be a SOI substrate. Generally, an SOI substrate includes a layer of a semiconductor material such as epitaxial silicon, germanium, silicon germanium, SOI, SGOI, or combinations thereof. In another embodiment, the substrate core 362 is an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate core 362.

The substrate core 362 may include active and passive devices (not separately illustrated). Devices such as transistors, capacitors, resistors, combinations thereof, and the like may be used to generate the structural and functional requirements of the design for the system. The devices may be formed using any suitable methods.

The substrate core 362 may also include metallization layers and vias, and bond pads over the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material, and may be formed through any suitable process (such as deposition, damascene, or the like). In some embodiments, the substrate core 362 is substantially free of active and passive devices.

The conductive connectors 330 are reflowed to attach the interposer 310 to the bond pads on the package substrate 360. The conductive connectors 330 connect the package component 300 to the package substrate 360, including metallization layers of the substrate core 362. Thus, the package substrate 360 is electrically connected to the stacked package 260. In some embodiments, passive devices (e.g., SMDs) may be attached to the package substrate 360, e.g., to the bond pads.

In some embodiments, an underfill (not shown) is formed between the package component 300 and the package substrate 360, surrounding the conductive connectors 330. The underfill may be formed by a capillary flow process after the package component is attached or may be formed by any suitable deposition method before the package component is attached.

In some embodiments, conductive connectors 366 are formed on the lower side of the package substrate 360, the lower side being opposite the package component 300. The conductive connectors 366 may be similar to the conductive connectors 220 described above and the description is not repeated herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments discussed herein may be discussed in a specific context, namely a device/structure with through substrate vias (TSVs) of different sizes. For example, a device could have larger TSVs (e.g., wider in a cross-sectional view) used for power and ground, and smaller TSVs (e.g., narrower in cross-sectional view) used for signal delivery. The disclosed device and method provide a solution that allows for both power and signal delivery, thereby enabling multi-stacking and offering a more flexible design.

The size of the TSVs, also known as the TSV critical dimension (CD), can affect the performance of the TSVs. Large TSV CDs are good for face-to-face (F2F) power delivery due to their low resistance, while small TSV CDs are good for face-to-back (F2B) die-to-die (D2D) communications due to their small pitch. However, both large and small TSV CDs have their drawbacks. Large TSV CDs cause high RC delay for signal communication, and small TSV CDs result in a high IR drop for power delivery. These issues constrained the design of System-on-Integrated-Circuit (SoIC) stacking, whether in a F2F or F2B configuration.

The disclosed device and method overcome these challenges by incorporating different TSV CDs in a single solution for both power and signal delivery. This approach allows for multi-stacking beyond just two-tier stacking, providing a more flexible design. Within a single tier, at least two different TSV CDs are formed to enable different SoIC stacking combinations, such as F2F and multiple F2B multi-stacking.

The disclosed device and method offer several advantages. They provide a more friendly design with less TSV area overhead. They offer an all-in-one solution for TSVs, making them an ideal solution for various package types. Furthermore, they enable high signal bandwidth, high-speed interconnects, and high-density integration for computing and high-power applications, such as Artificial Intelligence (AI) applications or deep learning.

In an embodiment, a device may include a first structure comprising a first surface and a second surface opposite the first surface. The first structure may include a first substrate and a first through substrate via (TSV) exposed from the second surface of the first substrate. The first TSV may have a first width. The device may also include a second TSV exposed from the second surface of the first structure, where the second TSV has a second width smaller than the first width. The device may further include a guard ring surrounding each of the first and second TSVs. Additionally, the device may include a second structure bonded to the first surface of the first structure, where the first surface has first bond pads.

The described embodiments may also include one or more of the following features. The device may include an active metallization pattern connected to active devices in the first structure. The first surface may be on a first side of the substrate, and the first interconnect structure may be on the first side of the substrate. The guard ring and the active metallization pattern may be in the first interconnect structure, and second bond pads may be on a second side of the substrate. The second bond pads may be electrically coupled to the first and second TSVs. The device may include a third structure bonded to the second bond pads of the first structure. The first and second structures may be bonded in a face-to-face configuration or a face-to-back configuration. Each of the first, second, and third structures may be semiconductor wafers or semiconductor dies. The device may include an interposer bonded to the third structure, where the third structure is between the first structure and the interposer. The device may also include a first die bonded to the interposer, where the interposer may include a local interconnect embedded within the interposer. The local interconnect may be coupled to the first die and the third structure. The first TSV may be a power or ground line, and the second TSV may be a communication line between the first and second structures.

In an embodiment, a method may include forming a first structure including a first surface and a second surface opposite the first surface. Forming the first structure may include forming a first interconnect structure over a first substrate, where the first interconnect structure has an active metallization pattern and a guard ring. The method may further include forming a first TSV through the first interconnect structure and the first substrate, where the guard ring surrounds the first TSV in the first interconnect structure. Additionally, the method may include forming first bond pads over the first interconnect structure and connecting them to the first TSV and the active metallization pattern of the first interconnect structure. The first bond pads may be on the first surface of the first structure. The method may also include forming a second structure including a first surface and a second surface opposite the first surface. After bonding the first surface of the first structure to the first surface of the second structure, the method may include forming a second TSV from the second surface of the first structure to the first interconnect structure. The second TSV may have a smaller width than the first TSV. The method may further include exposing the first TSV at the second surface of the first structure and forming second bond pads on the second surface of the first structure. The second bond pads may be electrically coupled to the first and second TSVs.

The described embodiments may also include one or more of the following features. The method may include forming a third structure including a first surface and a second surface opposite the first surface and bonding the second surface of the first structure to the first surface of the third structure with the second bond pads. The first and third structures may be semiconductor dies, and the second structure may be a semiconductor wafer. The method may include bonding the second surface of the third structure to an interposer, where the third structure is between the first structure and the interposer. The method may also include bonding a first die to the interposer, where the interposer has a local interconnect embedded within the interposer. The local interconnect may be coupled to the first die and the third structure. The first and second structures may be bonded in a face-to-face configuration or a face-to-back configuration.

In an embodiment, a method may include forming a first structure. Forming the first structure may include forming a first interconnect structure over a first substrate, where the first interconnect structure has a metallization pattern. The method may further include forming a first TSV through the first interconnect structure and the first substrate. Additionally, the method may include forming first bond pads over the first interconnect structure and connecting them to the first TSV and the metallization pattern of the first interconnect structure. The first bond pads may be on the first surface of the first structure. The method may also include bonding the first structure to a second structure. After bonding, the method may include forming a second TSV through the first substrate of the first structure to the first interconnect structure. The second TSV may have a smaller width than the first TSV. The method may further include thinning the first substrate, which exposes the first TSV. Additionally, the method may include forming second bond pads on the first wafer, where the second bond pads are electrically coupled to the first and second TSVs.

The described embodiments may also include one or more of the following features. The method may include bonding the second bond pads of the first wafer to a third structure having TSVs. The second structure may include a semiconductor die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a first structure comprising a first surface and a second surface opposite the first surface, wherein the first structure includes:
a first substrate;
a first through substrate via (TSV) extending through the first substrate, the first TSV having a first width;
a second TSV extending through the first substrate, the second TSV having a second width smaller than the first width;
a guard ring surrounding each of the first and second TSVs;
first bond pads on the first surface; and
a second structure directly bonded to the first bond pads on first surface of the first structure;
a third structure directly bonded to the second surface of the first structure; and
redistribution layers on the second surface of the first structure, the redistribution layers electrically coupled to the first and second TSVs, the redistribution layers being bonded to the third structure.

2. The semiconductor package structure of claim 1, wherein the first TSV is a power or ground line and the second TSV is a signal line.

3. The semiconductor package structure of claim 1, wherein the first, second, and third structures are semiconductor wafers.

4. The semiconductor package structure of claim 1, wherein the first, second, and third structures are semiconductor dies.

5. The semiconductor package structure of claim 1, wherein the first structure further comprises dummy metallization patterns adjacent to the guard rings.

6. The semiconductor package structure of claim 1, further comprising under-bump metallizations (UBMs) and conductive connectors on the redistribution layers.

7. The semiconductor package structure of claim 1, wherein the second structure comprises third TSVs having the second width.

8. A method, comprising:
forming a first structure including:
forming a first interconnect structure over a first substrate;
forming a first TSV through the first interconnect structure and the first substrate, the first TSV having a first width;
forming first bond pads over the first interconnect structure;
thinning the first substrate to expose the first TSV at a second surface of the first structure opposite a first surface;
bonding a second structure to the first surface of the first structure;
after bonding the second structure, forming a second TSV through the second structure, the second TSV having a second width smaller than the first width;
forming second bond pads on the second surface of the first structure, the second bond pads electrically coupled to the first and second TSVs; and
forming redistribution layers on the second bond pads.

9. The method of claim 8, wherein bonding the second structure comprises direct oxide-to-oxide bonding and direct metal-to-metal bonding.

10. The method of claim 8, further comprising forming a guard ring surrounding each of the first and second TSVs.

11. The method of claim 8, wherein forming the first and second TSVs comprises:
forming openings in the respective structures;
depositing a liner layer in the openings;
forming a seed layer on the liner layer; and
filling the openings with a conductive material.

12. The method of claim 8, further comprising bonding a third structure to the second structure.

13. The method of claim 8, further comprising forming under-bump metallizations (UBMs) and conductive connectors on the redistribution layers.

14. The method of claim 8, wherein the first TSV is formed to have a width less than 15 μm.

15. A system-in-package, comprising:
a first die layer including first TSVs having a first width;
a second die layer including second TSVs having a second width smaller than the first width;
a third die layer including third TSVs having the second width;
an encapsulant between the first, second, and third die layers;
an interposer including embedded local interconnects, the interposer coupled to the first die layer;
die-to-die connections between the first, second, and third die layers;
die-to-interposer connections between the first die layer and the interposer; and
external I/O connections on the interposer.

16. The system-in-package of claim 15, wherein the first TSVs are power or ground lines and the second and third TSVs are signal lines.

17. The system-in-package of claim 15, further comprising guard rings surrounding each of the first, second, and third TSVs.

18. The system-in-package of claim 15, wherein the die-to-die connections and die-to-interposer connections comprise direct oxide-to-oxide bonds and direct metal-to-metal bonds.

19. The system-in-package of claim 15, further comprising one or more dies coupled to the interposer.

20. The system-in-package of claim 15, wherein a ratio of the first width to the second width is in a range from 1.5 to 70.
